(19) United States
(12) Patent Application Publication
(10) Pub. No.: US 2024/0377742 A1
(43) Pub. Date: Nov. 14, 2024

(54) RADIATION-SENSITIVE RESIN COMPOSITION, METHOD OF FORMING RESIST PATTERN, AND POLYMER

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/782,428

(22) Filed: Jul. 24, 2024

Related U.S. Application Data
(63) Continuation of application No. PCT/JP2022/044273, filed on Nov. 30, 2022.

(30) Foreign Application Priority Data
Feb. 9, 2022 (JP) 2022-018949

(51) Int. Cl. G03F 7/039; G03F 7/004; G03F 7/16

(52) U.S. Cl. CPC G03F 7/0392; G03F 7/0045; G03F 7/161

(57) ABSTRACT

A radiation-sensitive resin composition includes: a polymer including a first structural unit represented by formula (1), solubility of the polymer in a developer solution capable of being altered by an acid; and a compound represented by formula (2). R¹ represents a hydrogen atom, or the like; R² represents a group obtained by removing, from a substituted or unsubstituted aliphatic hydrocarbon ring having 3 to 30 ring atoms, two hydrogen atoms; and Ar¹ represents a group obtained by removing one hydrogen atom from a substituted or unsubstituted aromatic hydrocarbon ring having 6 to 30 ring atoms. Z represents an acid-labile group; L¹ represents *—O—CO— or —O—; Y represents an organic group having 1 to 30 carbon atoms, the organic group not comprising a cyclic acetal structure; A⁻ represents a monovalent anion group; n is an integer of 1 to 5; and X⁺ represents a monovalent radiation-sensitive onium cation.

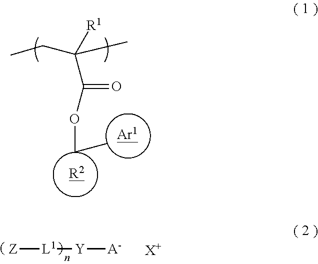

### CROSS-REFERENCE TO RELATED APPLICATIONS

The present application is a continuation application of International Patent Application No. PCT/JP2022/044273 filed Nov. 30, 2022, which claims priority to Japanese Patent Application No. 2022-018949 filed Feb. 9, 2022. The contents of these applications are incorporated herein by reference in their entirety.

### BACKGROUND OF THE DISCLOSURE

### Technical Field

The present disclosure relates to a radiation-sensitive resin composition, a method of forming a resist pattern, and a polymer.

### Discussion of the Background

A radiation-sensitive resin composition for use in microfabrication by lithography generates an acid at light-exposed regions upon an irradiation with a radioactive ray, e.g.: an electromagnetic wave such as a far ultraviolet ray such as an ArF excimer laser beam (wavelength of 193 nm) or a KrF excimer laser beam (wavelength of 248 nm), or an extreme ultraviolet ray (EUV) (wavelength of 13.5 nm); or a charged particle ray such as an electron beam. A chemical reaction in which the acid serves as a catalyst causes a difference between the light-exposed regions and light-unexposed regions in rates of dissolution in a developer solution, whereby a resist pattern is formed on a substrate.

Such radiation-sensitive resin compositions are required not only to have favorable sensitivity to exposure light such as the extreme ultraviolet ray and the electron beam, but also to result in superiority in terms of CDU (Critical Dimension Uniformity) performance, an ability to inhibit development defects, and the like.

To meet these requirements, types, molecular structures, and the like of polymers, acid generating agents, and other components which may be used in radiation-sensitive resin compositions have been investigated, and combinations thereof have been further investigated in detail (see Japanese Unexamined Patent Applications, Publication Nos. 2010-134279, 2014-224984, and 2016-047815).

### SUMMARY

According to one aspect of the disclosure, a radiation-sensitive resin composition (hereinafter, may be also referred to as “composition (I)”) contains: a polymer (hereinafter, may be also referred to as “(A1) polymer” or “polymer (A1)”) having a first structural unit represented by the following formula (1), solubility of the polymer (A1) in a developer solution being capable of being altered by an action of an acid; and a compound (hereinafter, may be also referred to as “(Z) compound” or “compound (Z)”) represented by the following formula (2).

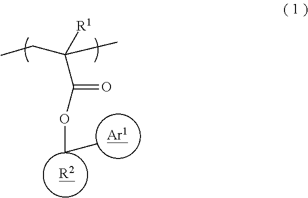

In the above formula (1),
R¹ represents a hydrogen atom, a fluorine atom, a methyl group, or a trifluoromethyl group;
R² represents a group obtained by removing, from a substituted or unsubstituted aliphatic hydrocarbon ring having 3 to 30 ring atoms, two hydrogen atoms which bond to one carbon atom; and
Ar¹ represents a group obtained by removing one hydrogen atom from a substituted or unsubstituted aromatic hydrocarbon ring having 6 to 30 ring atoms.

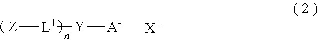

In the above formula (2),
Z represents an acid-labile group;
L¹ represents *—O—CO— or —O—, wherein * denotes a site bonding to Z;
Y represents an organic group having 1 to 30 carbon atoms and having a valency of (n+1), the organic group not containing a cyclic acetal structure;
A⁻ represents a monovalent anion group;
n is an integer of 1 to 5, wherein in a case in which n is no less than 2, two or more Zs are identical or different from each other, and two or more L¹s are identical or different from each other; and
X⁺ represents a monovalent radiation-sensitive onium cation.

According to an other aspect of the disclosure, a radiation-sensitive resin composition (hereinafter, may be also referred to as “composition (II)”) contains: a polymer (hereinafter, may be also referred to as “(A2) polymer” or “polymer (A2)”) having: a first structural unit represented by the following formula (1); and a third structural unit represented by the following formula (3-2), solubility of the polymer (A2) in a developer solution being capable of being altered by an action of an acid; and a radiation-sensitive acid generating agent (hereinafter, may be also referred to as “(B) acid generating agent” or “acid generating agent (B)”).

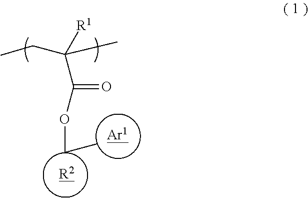

In the formula (1),
R¹ represents a hydrogen atom, a fluorine atom, a methyl group, or a trifluoromethyl group;
R² represents a group obtained by removing, from a substituted or unsubstituted aliphatic hydrocarbon ring having 3 to 30 ring atoms, two hydrogen atoms which bond to one carbon atom; and
Ar¹ represents a group obtained by removing one hydrogen atom from a substituted or unsubstituted aromatic hydrocarbon ring having 6 to 30 ring atoms.

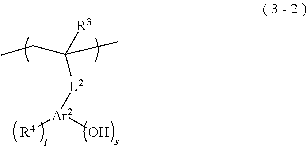

In the formula (3-2),
R³ represents a hydrogen atom, a fluorine atom, a methyl group, or a trifluoromethyl group;
L² represents a single bond, —COO—, —O—, or —CONH—;
Ar² represents a group obtained by removing (s+t+1) hydrogen atoms from an aromatic hydrocarbon ring having 6 to 30 ring atoms;
s is an integer of 1 to 3, wherein
   in a case in which s is 1, the hydroxy group bonds to, of the carbon atoms constituting Ar², the carbon atom adjacent to the carbon atom which bonds to L², and
   in a case in which s is no less than 2, at least one of the hydroxy groups bonds to, of the carbon atoms constituting Ar², the carbon atom adjacent to the carbon atom which bonds to L²; and
t is an integer of 0 to 8, wherein
   in a case in which tis 1, R⁴ represents a halogen atom or a monovalent organic group having 1 to 10 carbon atoms, and
   in a case in which t is no less than 2, a plurality of R⁴s are identical or different from each other, and each R⁴ represents a halogen atom or a monovalent organic group having 1 to 10 carbon atoms, or two or more of the plurality of R⁴s taken together represent an aliphatic ring having 4 to 20 ring atoms together with the carbon chain to which the two or more of the plurality of R⁴s bond.

According to a still other aspect of the disclosure, a method of forming a resist pattern includes: applying the above-described radiation-sensitive resin composition (the composition (I) or the composition (II)) directly or indirectly on a substrate to form a resist film; exposing the resist film; and developing the resist film exposed.

Yet another aspect of the disclosure is the polymer (A2).

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

The radiation-sensitive resin composition of the present disclosure is superior in sensitivity, and results in superiority in CDU performance and the ability to inhibit development defects. The method of forming a resist pattern of the present disclosure enables forming a resist pattern being superior in CDU performance and in which the occurrence of development defects is inhibited, with high sensitivity. The polymer of the present disclosure can be suitably used as a component of the radiation-sensitive resin composition of the present disclosure.

Therefore, these can be suitably used in manufacturing processes of semiconductor devices, in which further progress of miniaturization is expected in the future.

Hereinafter, the radiation-sensitive resin composition, the method of forming a resist pattern, and the polymer of embodiments of the present disclosure are described in detail.

### Radiation-Sensitive Resin Composition

Modes of the radiation-sensitive resin composition of one embodiment of the present disclosure may be exemplified by the following composition (I) and composition (II).
Composition (I): contains the polymer (A1) and the compound (Z).
Composition (II): contains the polymer (A2) and the acid generating agent (B).

In the present specification, the polymer (A1) and the polymer (A2) may be referred to as “(A) polymer” or “polymer (A)” in combination.

As described later, the polymer (A2) is encompassed in the polymer (A1), and the acid generating agent (B) is a radiation-sensitive acid generating agent other than the compound (Z). Thus, the radiation-sensitive resin composition containing the polymer (A2) and the compound (Z) is a mode of the composition (I).

Hereinafter, the radiation-sensitive resin composition of the one embodiment of the present disclosure is described in the order of the composition (I) and the composition (II).

### Composition (I)

The composition (I) contains the polymer (A1) and the compound (Z). The composition (I) typically contains an organic solvent (hereinafter, may be also referred to as “(D) organic solvent” or “organic solvent (D)”). The composition (I) may contain, as favorable component(s), a radiation-sensitive acid generating agent (hereinafter, may be also referred to as “(B) acid generating agent” or “acid generating agent (B)”) other than the compound (Z), and/or an acid diffusion control agent (hereinafter, may be also referred to as “(C) acid diffusion control agent” or “acid diffusion control agent (C)”) other than the compound (Z). The composition (I) may contain, as a favorable component, a polymer (hereinafter, may be also referred to as “(F) polymer” or “polymer (F)”) having a percentage content of fluorine atoms which is higher than that of the polymer (A). The composition (I) may contain, within a range not leading to impairment of the effects of the present invention, other optional component(s).

Due to the polymer (A1) and the compound (Z) being contained, the composition (I) is superior in sensitivity, and results in superiority in CDU performance and the ability to inhibit development defects. Although not necessarily clarified and without wishing to be bound by any theory, the reason for achieving the aforementioned effects by the composition (I) due to involving such a constitution is presumed to be, for example, as in the following. Due to the polymer (A1) and the compound (Z) each having specific structures as described later, solubility or insolubility in a developer solution in light-exposed regions improves. It is considered that as a result, the composition (I) is superior in sensitivity, and results in superiority in CDU performance and the ability to inhibit development defects.

The composition (I) may be prepared, for example, by mixing the polymer (A1) and the compound (Z), as well as, as needed, the acid generating agent (B), the acid diffusion controller (C), the organic solvent (D), and the other optional component(s), in a certain ratio, and preferably filtering a thus resulting mixture through a membrane filter having a pore size of no greater than 0.2 μm.

Each component contained in the composition (I) is described below.

### (A1) Polymer

The polymer (A1) has a first structural unit (hereinafter, may be also referred to as “structural unit (I)”) represented by the formula (1), described later, and solubility of the polymer (A1) in a developer solution is capable of being altered by an action of an acid. Due to the polymer (A1) having the structural unit (I), the property of altering the solubility in a developer solution by an action of an acid is exhibited. The composition (I) may contain one, or two or more types of the polymer (A).

It is preferred that the polymer (A1) further has a structural unit (hereinafter, may be also referred to as “structural unit (II)”) that includes a phenolic hydroxy group. The polymer (A1) may further have another structural unit (hereinafter, may be also simply referred to as “other structural unit”) aside from the structural unit (I) and the structural unit (II). The polymer (A1) may have one, or two or more types of each structural unit.

There may be a case in which the structural units contained in the polymer (A1) can be considered to fall under two or more categories of structural units in an overlapping manner (for example, a case in which a certain structural unit which is categorized as being the structural unit (II) can be considered to fall under not only the structural unit (II), but also a structural unit other than the structural unit (II)). In the present specification, such a structural unit is treated as falling under the lowest parenthesized number for the structural unit.

The lower limit of a proportion of the polymer (A1) in the composition (I) with respect to total components other than the organic solvent (D) contained in the composition (I) is preferably 50% by mass, more preferably 70% by mass, and still more preferably 80% by mass. The upper limit of the proportion is preferably 99% by mass, and more preferably 95% by mass.

The lower limit of a polystyrene-equivalent weight average molecular weight (Mw) of the polymer (A1) as determined by gel permeation chromatography (GPC) is preferably 1,000, more preferably 3,000, still more preferably 4,000, yet more preferably 5,000, and particularly preferably 6,000. The upper limit of the Mw is preferably 50,000, more preferably 30,000, still more preferably 20,000, yet more preferably 15,000, and particularly preferably 10,000. When the Mw of the polymer (A1) falls within the above range, coating characteristics of the composition (I) may be improved. The Mw of the polymer (A1) can be adjusted by, for example, regulating the type, the amount, and the like of a polymerization initiator used in synthesis of the polymer (A1).

The upper limit of a ratio (hereinafter may be also referred to as “Mw/Mn” or “polydispersity index”) of the Mw to a polystyrene-equivalent number average molecular weight (Mn) of the polymer (A1) as determined by GPC is preferably 2.5, more preferably 2.0, and still more preferably 1.8. The lower limit of the ratio is typically 1.0, preferably 1.1, more preferably 1.2, and still more preferably 1.3.

### Method for Measuring Mw and Mn

As referred to herein, the Mw and Mn of the polymer are values measured by using gel permeation chromatography (GPC) under the following conditions.
GPC columns: “G2000 HXL”×2, “G3000 HXL”×1, and “G4000 HXL”×1,
available from Tosoh Corporation
column temperature: 40° C.
elution solvent: tetrahydrofuran
flow rate: 1.0 mL/min
sample concentration: 1.0% by mass
amount of injected sample: 100 uL
detector: differential refractometer
standard substance: mono-dispersed polystyrene

The polymer (A1) can be synthesized by, for example, polymerizing a monomer that gives each structural unit in accordance with a well-known procedure.

Each structural unit contained in the polymer (A1) is described below.

### Structural Unit (I)

The structural unit (I) is represented by the following formula (1).

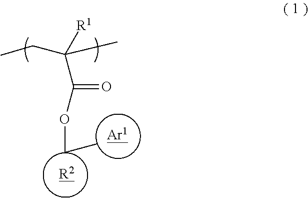

In the above formula (1), R¹ represents a hydrogen atom, a fluorine atom, a methyl group, or a trifluoromethyl group; R² represents a group obtained by removing, from a substituted or unsubstituted aliphatic hydrocarbon ring having 3 to 30 ring atoms, two hydrogen atoms which bond to one carbon atom; and Ar¹ represents a group obtained by removing one hydrogen atom from a substituted or unsubstituted aromatic hydrocarbon ring having 6 to 30 ring atoms.

The polymer (A1) may have one, or two or more types of the structural unit (I).

The structural unit (I) is a structural unit that includes an acid-labile group. The “acid-labile group” as referred to herein means a group that substitutes for a hydrogen atom in a carboxy group, and is capable of being dissociated by an action of an acid to give a carboxy group. In the above formula (1), the group (the group represented by the following formula (a)) bonded to the ethereal oxygen atom in the carbonyloxy group is the acid-labile group (hereinafter, may be also referred to as “acid-labile group (a)”).

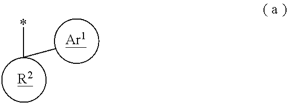

In the above formula (a), R² and Ar¹ are as defined in the above formula (1); and * denotes a site bonding to the ethereal oxygen atom in the carbonyloxy group in the above formula (1).

Due to using the composition (I), the acid-labile group (a) is dissociated from the structural unit (I) by an action of an acid generated from the compound (Z) and/or the like by exposure, creating a difference in solubility of the polymer (A1) in a developer solution between light-exposed regions and light-unexposed regions and thus enabling a resist pattern to be formed. The polymer (A1) containing the acid-labile group (a) in the structural unit (I) is considered to be one factor in the composition (I) exhibiting superior sensitivity.

The number of “ring atoms” as referred to means the number of atoms constituting a ring structure, and in a case of a polycyclic ring, the number of “ring atoms” means the number of atoms constituting the polycyclic ring. The “polycyclic ring” encompasses not only a spiro-type polycyclic ring in which two rings have one shared atom and a fused polycyclic ring in which two rings have two shared atoms, but also a ring-assembled polycyclic ring in which two rings are connected by a single bond without having any shared atom. The “ring structure” encompasses an “aliphatic ring” and an “aromatic ring”. The “aliphatic ring” encompasses an “aliphatic hydrocarbon ring” and an “aliphatic heterocycle”. The “aromatic ring” encompasses an “aromatic hydrocarbon ring” and an “aromatic heterocycle”. A “group obtained by removing X hydrogen atoms from a ring” as referred to means a group obtained by removing X hydrogen atoms bonding to an atom constituting a ring structure.

In light of copolymerizability of a monomer that gives the structural unit (I), R¹ represents preferably a hydrogen atom or a methyl group, and more preferably a hydrogen atom.

Examples of the aliphatic hydrocarbon ring having 3 to 30 ring atoms that gives R² include: monocyclic saturated aliphatic rings such as a cyclopropane ring, a cyclobutane ring, a cyclopentane ring, and a cyclohexane ring; polycyclic saturated aliphatic rings such as a norbornane ring and an adamantane ring; monocyclic unsaturated aliphatic rings such as a cyclobutene ring, a cyclopentene ring, and a cyclohexene ring; polycyclic unsaturated aliphatic rings such as a norbornene ring; and the like. Of these, the monocyclic saturated aliphatic ring is preferred, and a cyclohexane ring is more preferred.

A part or all of hydrogen atoms bonded to carbon atoms constituting the aliphatic hydrocarbon ring may be substituted with a substituent. Examples of the substituent include: halogen atoms such as a fluorine atom and an iodine atom; a hydroxy group; a carboxy group; a cyano group; a nitro group; an alkyl group; an alkoxy group; an alkoxycarbonyl group; an alkoxycarbonyloxy group; an acyl group; an acyloxy group; an oxo group (═O); and the like.

The aliphatic hydrocarbon ring is preferably an unsubstituted aliphatic hydrocarbon ring.

R² represents a group obtained by removing, from the aliphatic hydrocarbon ring, two hydrogen atoms which bond to one carbon atom. In other words, R² represents a divalent group in which two atomic bonds are present in one carbon atom which constitutes the aliphatic hydrocarbon ring. In the above formula (1), the ethereal oxygen atom in the carbonyloxy group and Ar¹ are bonded to the same carbon atom in R². Due to having such a structure, the acid-labile group (a) is dissociated from the structural unit (I) by an action of an acid generated by exposure, generating the carboxy group.

Examples of the aromatic hydrocarbon ring structure having 6 to 30 ring atoms which gives Ar¹ include: a benzene ring; fused polycyclic aromatic hydrocarbon rings such as a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; and the like. Of these, a benzene ring is preferred.

A part or all of hydrogen atoms bonded to the carbon atoms constituting the aromatic hydrocarbon ring may be substituted with a substituent. Examples of the substituent include substituents similar to those exemplified as the substituent which may be contained in the aliphatic hydrocarbon ring, and the like. Of these, the halogen atom is preferred, and a fluorine atom or an iodine atom is more preferred.

The acid-labile group (a) is preferably a 1-phenylcyclohexan-1-yl group.

The lower limit of a proportion of the structural unit (I) in the polymer (A1) contained with respect to total structural units constituting the polymer (A1) is preferably 1 mol %, more preferably 5 mol %, and still more preferably 10 mol %. The upper limit of the proportion is preferably 60 mol %, more preferably 50 mol %, and still more preferably 40 mol %. When the proportion of the structural unit (I) falls within the above range, the sensitivity of, and the CDU performance and ability to inhibit development defects resulting from the composition (I) can be further improved. It is to be noted that with regard to descriptions of the upper limit and the lower limit of numerical ranges as referred to herein, unless otherwise specified particularly, the upper limit may have the meaning of either “no greater than” or “less than”, and the lower limit may have the meaning of either “no less than” or “greater than”. Furthermore, the upper limit value and the lower limit value may be combined ad libitum.

### Structural Unit (II)

The structural unit (II) is a structural unit that includes a phenolic hydroxy group. The “phenolic hydroxy group” as referred to means a hydroxy group directly bonding to an aromatic ring in general, without being limited to a hydroxy group directly bonding to a benzene ring. The polymer (A1) may include one, or two or more types of the structural unit (II).

In the case of exposure to KrF, exposure to EUV, or exposure to an electron beam, the sensitivity of the composition (I) to exposure light can be further improved when the polymer (A1) has the structural unit (II). Therefore, in the case in which the polymer (A1) has the structural unit (II), the composition (I) can be suitably used as a radiation-sensitive resin composition for exposure to KrF, exposure to EUV, or exposure to an electron beam.

Examples of the structural unit (II) include a structural unit (hereinafter, may be also referred to as “structural unit (II-1)”) represented by the following formula (3-1), and the like.

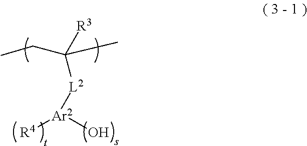

In the above formula (3-1), R³ represents a hydrogen atom, a fluorine atom, a methyl group, or a trifluoromethyl group; L² represents a single bond, —COO—, —O—, or —CONH—; Ar² represents a group obtained by removing (s+t+1) hydrogen atoms from an aromatic hydrocarbon ring having 6 to 30 ring atoms; s is an integer of 1 to 3; and t is an integer of 0 to 8, wherein in a case in which tis 1, R⁴ represents a halogen atom or a monovalent organic group having 1 to 20 carbon atoms, and in a case in which t is no less than 2, a plurality of R⁴s are identical or different from each other, and each R⁴ represents a halogen atom or a monovalent organic group having 1 to 20 carbon atoms, or two or more of the plurality of R⁴s taken together represent an aliphatic ring having 4 to 20 ring atoms together with the carbon chain to which the two or more of the plurality of R⁴s bond.

The number of “carbon atoms” as referred to means the number of carbon atoms constituting a group. The “organic group” as referred to means a group that contains at least one carbon atom. The “valency” of a group means the number of atoms to which that group bonds.

In light of copolymerizability of a monomer that gives the structural unit (II-1), R³ represents preferably a hydrogen atom or a methyl group.

L² is preferably a single bond or —COO—.

Examples of the aromatic hydrocarbon ring having 6 to 30 ring atoms which gives Ar² include structures similar to those exemplified as the aromatic hydrocarbon ring having 6 to 30 ring atoms that gives Ar¹ in the above formula (1), and the like. Of these, a benzene ring is preferred.

s is preferably 1 or 2, and more preferably 1.

The halogen atom which may be represented by R⁴ is a fluorine atom, a chlorine atom, a bromine atom, or an iodine atom.

The monovalent organic group having 1 to 20 carbon atoms which may be represented by R⁴ is exemplified by: a monovalent hydrocarbon group having 1 to 20 carbon atoms; a group (a) that contains a divalent heteroatom-containing group between a carbon-carbon bond of this monovalent hydrocarbon group; a group (B) obtained by substituting with a monovalent heteroatom-containing group, a part or all of hydrogen atoms included in the monovalent hydrocarbon group or the group (a); a group (Y) obtained by combining the monovalent hydrocarbon group, the group (a), or the group (B) with a divalent heteroatom-containing group; and the like.

The “hydrocarbon group” encompasses both an “aliphatic hydrocarbon group” and an “aromatic hydrocarbon group”. The “aliphatic hydrocarbon group” encompasses both a “saturated hydrocarbon group” and an “unsaturated hydrocarbon group”. From a different viewpoint, the “aliphatic hydrocarbon group” encompasses both a “chain hydrocarbon group” and an “alicyclic hydrocarbon group”. The “chain hydrocarbon group” as referred to means a hydrocarbon group not including a ring structure but being constituted with only a chain structure, and encompasses both a linear hydrocarbon group and a branched hydrocarbon group. The “alicyclic hydrocarbon group” as referred to means a hydrocarbon group that includes, as a ring structure, not an aromatic ring but an aliphatic ring alone, and encompasses both a monocyclic alicyclic hydrocarbon group and a polycyclic alicyclic hydrocarbon group. In this regard, it is not necessary for the alicyclic hydrocarbon group to be constituted with only an aliphatic ring; a chain structure may be included in a part thereof. The “aromatic hydrocarbon group” as referred to means a hydrocarbon group that includes an aromatic ring as a ring structure. In this regard, it is not necessary for the aromatic hydrocarbon group to be constituted with only an aromatic ring; a chain structure or an aliphatic ring may be included in a part thereof.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an isobutyl group, and a tert-butyl group; alkenyl groups such as an ethenyl group, a propenyl group, a butenyl group, and a 2-methylprop-1-en-1-yl group; alkynyl groups such as an ethynyl group, a propynyl group, and a butynyl group; and the like.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; polycyclic alicyclic unsaturated hydrocarbon groups such as a norbornenyl group, a tricyclodecenyl group, and a tetracyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

Exemplary heteroatoms which may constitute the monovalent or divalent heteroatom-containing group include an oxygen atom, a nitrogen atom, a sulfur atom, a phosphorus atom, a silicon atom, a halogen atom, and the like.

Examples of the monovalent heteroatom-containing group include a halogen atom, a hydroxy group, a carboxy group, a cyano group, an amino group, a sulfanyl group (—SH), an oxo group (═O), and the like.

The divalent heteroatom-containing group is exemplified by —O—, —CO—, —S—, —CS—, —NR′—, groups obtained by combining two or more of these (for example, —COO—, —CONR′—, etc.), and the like. R′ represents a hydrogen atom or a monovalent hydrocarbon group having 1 to 10 carbon atoms. Examples of the monovalent hydrocarbon group having 1 to 10 carbon atoms represented by R′ include, of the groups exemplified above as the “monovalent hydrocarbon group having 1 to 20 carbon atoms”, those having 1 to 10 carbon atoms, and the like.

Examples of the aliphatic ring having 4 to 20 ring atoms which may be represented by the two or more of the plurality of R⁴s taken together, together with the carbon chain to which the two or more of the plurality of R⁴s bond include: monocyclic saturated aliphatic rings such as a cyclobutane ring, a cyclopentane ring, and a cyclohexane ring; polycyclic saturated aliphatic rings such as a norbornane ring, an adamantane ring, a tricyclodecane ring, and a tetracyclododecane ring; monocyclic unsaturated aliphatic rings such as a cyclopropene ring, a cyclobutene ring, a cyclopentene ring, and a cyclohexene ring; polycyclic unsaturated aliphatic rings such as a norbornene ring, a tricyclodecene ring, and a tetracyclododecene ring; and the like.

t is preferably 0 or 1.

Examples of the structural unit (II-1) include structural units (hereinafter, may be also referred to as “structural units (II-1-1) to (II-1-18)”) represented by the following formulae (3-1-1) to (3-1-18), and the like. Of these, the structural unit (3-1-1), the structural unit (3-1-3), the structural unit (3-1-8), the structural unit (3-1-9), the structural unit (3-1-12), or a combination thereof is preferred.

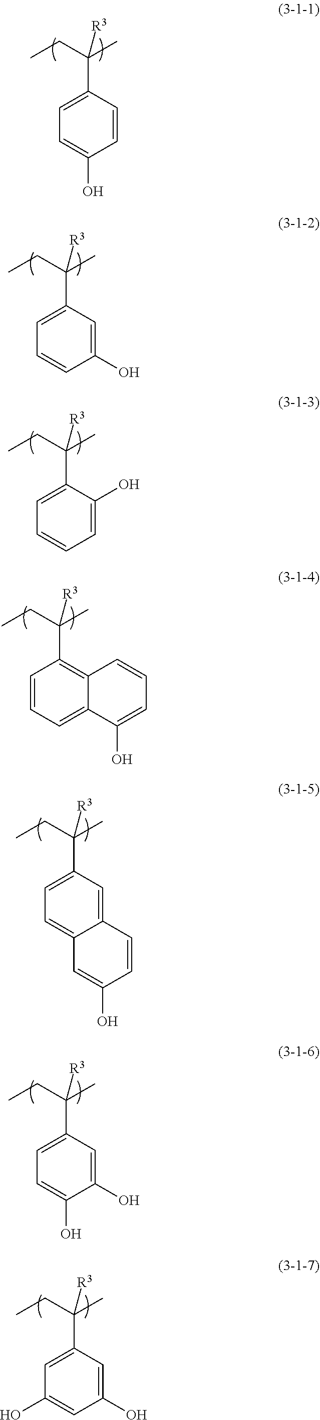

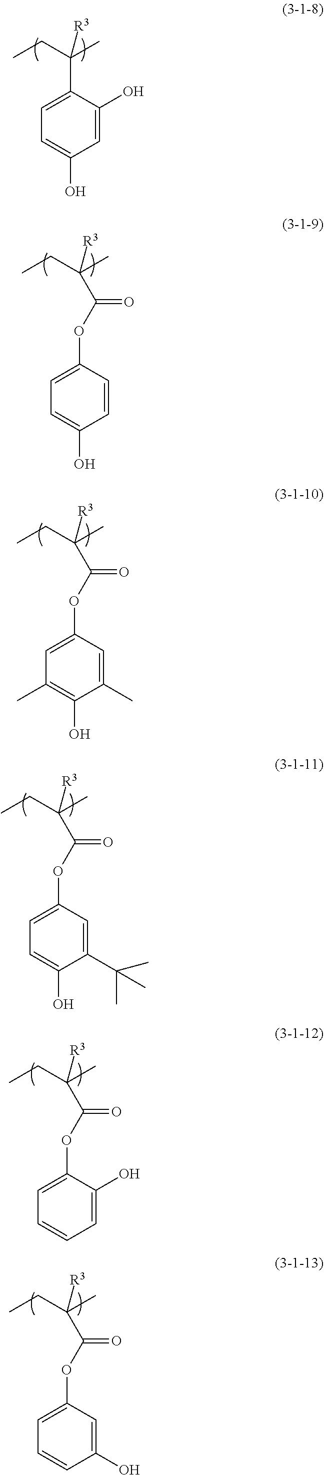

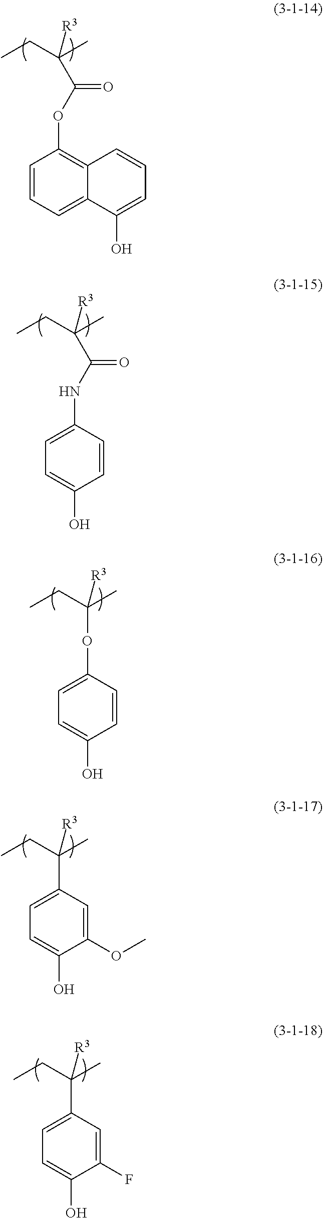

In the above formulae (3-1-1) to (3-1-18), R³ is as defined in the above formula (3-1).

In a case in which the polymer (A1) has the structural unit (II-1), the lower limit of a proportion of the structural unit (II-1) in the polymer (A1) with respect to the total structural units constituting the polymer (A1) is preferably 20 mol %, more preferably 30 mol %, and still more preferably 40 mol %. The upper limit of the proportion is preferably 70 mol %, more preferably 60 mol %, and still more preferably 50 mol %.

From another viewpoint, the structural unit (II-1) is preferably a structural unit represented by the formula (3-2), described later. In this case, the ability to inhibit development defects can be further improved.

### Structural Unit (IIa)

The structural unit (IIa) is a type of the structural unit which contains a phenolic hydroxy group (structural unit (II)), and is a structural unit represented by the following formula (3-2). The following formula (3-2) is a type of the above formula (3-1), and specifies the site to which the hydroxy group bonds. It is to be noted that the polymer (A1) which further has the structural unit (IIa) is the polymer (A2).

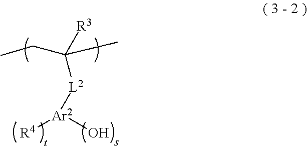

In the formula (3-2), R³, L², R⁴, Ar², s, and t are as defined in the above formula (3-1); however, in a case in which s is 1, the hydroxy group bonds to, of the carbon atoms constituting Ar², the carbon atom adjacent to the carbon atom which bonds to L², and in a case in which s is no less than 2, at least one of the hydroxy groups bonds to, of the carbon atoms constituting Ar², the carbon atom adjacent to the carbon atom which bonds to L².

Of the structural units which may be represented by the above formula (3-1), the structural unit (IIa) is one in which at least one of the hydroxy groups bonds to, of the carbon atoms constituting Ar², the carbon atom adjacent to the carbon atom which bonds to L². In other words, at least one hydroxy group and L² preferably bond to each of ortho positions in Ar². In still other words, the carbon atom on Ar² to which L² bonds is directly bonded to one of the carbon atoms on Ar² to which the hydroxy group bonds.

When the polymer (A1) has the structural unit (IIa), the ability to inhibit development defects can be further improved. Although not necessarily clarified and without wishing to be bound by any theory, the reason for exhibiting such an effect is presumed to be as follows, for example. As described above, due to the polymer (A) and the compound (Z) each having the specific structure, solubility or insolubility in a developer solution in light-exposed regions is improved. Furthermore, when the polymer (A) has the structural unit (IIa), the interaction between the polymer (A), the compound (Z), and the like can be appropriately adjusted, whereby the solubility or insolubility in a developer solution in light-exposed regions can be further improved. It is considered that as a result, the composition (I) can exhibit the ability to inhibit development defects in a more superior manner.

The structural unit (IIa) is preferably the structural unit (structural unit (II-1-3)) represented by the above formula (3-1-3), the structural unit represented by the above formula (3-1-8), the structural unit (structural unit (II-1-12)) represented by the above formula (3-1-12), or a combination thereof, and more preferably the structural unit (II-1-3), the structural unit (II-1-12), or a combination thereof. In this case, the ability to inhibit development defects can be still further improved.

In the case in which the polymer (A1) has the structural unit (IIa), the lower limit of a proportion of the structural unit (IIa) in the polymer (A1) with respect to the total structural units constituting the polymer (A1) is preferably 10 mol %, more preferably 20 mol %, and still more preferably 30 mol %. The upper limit of the proportion is preferably 70 mol %, more preferably 60 mol %, and still more preferably 50 mol %.

In the case in which the polymer (A1) has the structural unit (IIa), the polymer (A1) may contain, of the structural unit (II), a structural unit (hereinafter, may be also referred to as “structural unit (IIb)”) other than the structural unit (IIa). A proportion of the structural unit (IIb) in the polymer (A1) in this case can be appropriately adjusted based on the proportion of the structural unit (IIa), described above, within the range of the proportion of the structural unit (II), described above.

### Other Structural Unit(s)

The other structural unit(s) may be exemplified by a structural unit (hereinafter, may be also referred to as “structural unit (III)”) including an acid-labile group other than the acid-labile group (a); a structural unit (hereinafter, may be also referred to as “structural unit (IV)”) including a lactone structure, a cyclic carbonate structure, a sultone structure, or a combination thereof; a structural unit (hereinafter, may be also referred to as “structural unit (V)”) including an alcoholic hydroxy group; and the like.

### Structural Unit (III)

The structural unit (III) includes an acid-labile group (hereinafter, may be also referred to as “acid-labile group (b)”) other than the acid-labile group (a). The structural unit (III) is a structural unit which is different from the structural unit (I).

Examples of the structural unit (III) include structural units (hereinafter, may be also referred to as “structural units (III-1) to (III-3)”) represented by the following formulae (III-1) to (III-3), and the like. It is to be noted that in the following formula (III-1), —C(R^{X})(R^{Y})(R^{Z}), which bonds to an ethereal oxygen atom derived from the carboxy group, falls under the acid-labile group (b).

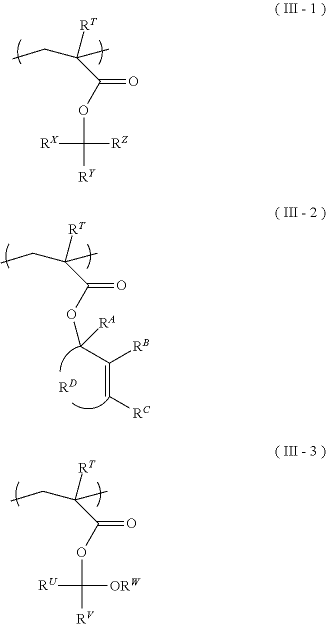

In each of the above formulae (III-1) to (III-3), each RT independently represents a hydrogen atom, a fluorine atom, a methyl group, or a trifluoromethyl group.

In the above formula (III-1), R^{X} represents a substituted or unsubstituted monovalent hydrocarbon group having 1 to 20 carbon atoms; and R^{Y} and R^{Z} each independently represent a monovalent hydrocarbon group having 1 to 20 carbon atoms, or R^{Y} and R^{Z} taken together represent a saturated aliphatic ring having 3 to 20 ring atoms, together with the carbon atom to which R^{Y} and R^{Z} bond, wherein in a case in which R^{Y} and R^{Z} taken together represent the saturated aliphatic ring, R^{X} represents a substituted or unsubstituted monovalent aliphatic hydrocarbon ring having 1 to 20 carbon atoms.

In the above formula (III-2), R^{A} represents a hydrogen atom; R^{B} and R^{C} each independently represent a hydrogen atom or a monovalent hydrocarbon group having 1 to 20 carbon atoms; and RD represents a divalent hydrocarbon group having 1 to 20 carbon atoms which constitutes an unsaturated aliphatic ring having 4 to 20 ring atoms, together with the carbon atom to which each of R^{A}, R^{B}, and R^{C} bonds.

In the above formula (III-3), R^{U} and R^{V} each independently represent a hydrogen atom or a monovalent hydrocarbon group having 1 to 20 carbon atoms, and R^{W} represents a monovalent hydrocarbon group having 1 to 20 carbon atoms, or R^{U} and R^{V} taken together represent an aliphatic ring having 3 to 20 ring atoms together with the carbon atom to which R^{U} and R^{V} bond, or R^{U} and R^{W} taken together represent an aliphatic heterocycle having 4 to 20 ring atoms together with the carbon atom to which R^{U} bonds and the oxygen atom to which R^{W} bonds.

In light of copolymerizability of a monomer that gives the structural unit (III), RT represents preferably a hydrogen atom or a methyl group.

Examples of the monovalent hydrocarbon group having 1 to 20 carbon atoms which may be represented by R^{X}, R^{Y}, R^{Z}, R^{B}, R^{C}, R^{U}, R^{V}, or R^{U} include groups similar to those exemplified in the above formula (3-1) as the monovalent hydrocarbon group having 1 to 20 carbon atoms, of the monovalent organic group having 1 to 20 carbon atoms which may be represented by R⁴, and the like.

Examples of the substituent which may be contained in the hydrocarbon group represented by R^{X} include substituents similar to those exemplified as the substituent which may be contained in the aliphatic hydrocarbon ring which gives R² in the above-described formula (1), and the like.

Examples of the saturated aliphatic ring having 3 to 20 ring atoms which may be represented by R^{Y} and R^{Z} taken together, together with the carbon atom to which R^{Y} and R^{Z} bond, and the aliphatic ring having 3 to 20 ring atoms which may be represented by R^{U} and R^{V} taken together, together with the carbon atom to which R^{U} and R^{V} bond, include structures similar to those exemplified in the explanation of the above formula (1), and the like.

Examples of the divalent hydrocarbon group having 1 to 20 carbon atoms represented by RD include groups obtained by removing one hydrogen atom from the groups exemplified as the monovalent hydrocarbon group having 1 to 20 carbon atoms which may be represented by R^{X}, R^{Y}, R^{Z}, R^{B}, R^{C}, R^{U}, R^{V}, or R^{W}, described above; and the like.

Examples of the unsaturated aliphatic ring having 4 to 20 ring atoms represented by RD, together with the three carbon atoms to which R^{A}, R^{B}, and R^{C} respectively bond, include the structures exemplified in the explanation of the above formula (1), and the like.

Examples of the aliphatic heterocycle having 4 to 20 ring atoms which may be represented by R^{U} and R^{W} taken together, together with the carbon atom to which R^{U} bonds and the oxygen atom to which R^{W} bonds, include an oxacyclobutane ring, an oxacyclopentane ring, an oxacyclohexane ring, an oxacyclobutene ring, an oxacyclopentene ring, an oxacyclohexene ring, and the like.

In the case in which each of R^{Y} and R^{Z} represents the monovalent hydrocarbon group having 1 to 20 carbon atoms, each of R^{Y} and R^{Z} is preferably a chain hydrocarbon group, more preferably an alkyl group, and still more preferably a methyl group. R^{X} in this case is preferably a substituted or unsubstituted aromatic hydrocarbon group, more preferably a substituted or unsubstituted aryl group, and still more preferably a phenyl group, a 4-fluorophenyl group, or a 4-iodophenyl group.

In the case in which R^{Y} and R^{Z} taken together represent the saturated aliphatic ring having 3 to 20 ring atoms together with the carbon atom to which R^{Y} and R^{Z} bond, the saturated aliphatic ring is preferably the monocyclic saturated aliphatic ring or the polycyclic saturated aliphatic ring, and more preferably a cyclopentane ring, an adamantane ring, or a tetracyclododecane ring. R^{X} in this case represents preferably a substituted or unsubstituted chain hydrocarbon group, more preferably a substituted alkyl group, and still more preferably a methyl group or an ethyl group.

The structural unit (III) is preferably the structural unit (III-1).

The structural unit (III-1) is preferably a structural unit represented by the following formulae (III-1-1) to (III-1-4).

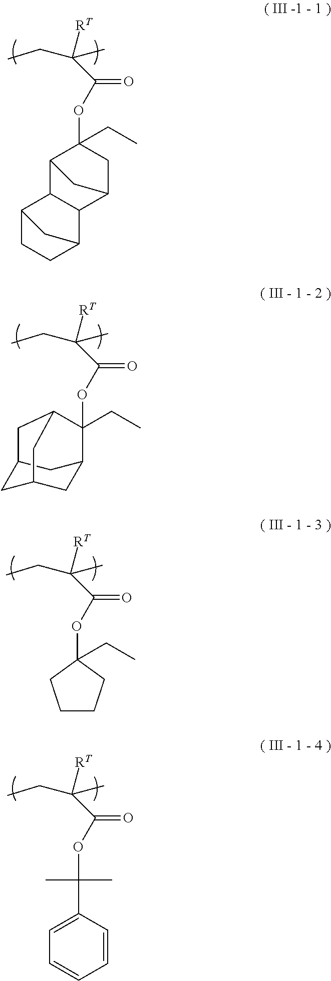

In the above formulae (III-1-1) to (III-1-4), RT is as defined in the above formula (III-1).

In the case in which the polymer (A1) has the structural unit (III), the lower limit of a proportion of the structural unit (III) contained with respect to the total structural units constituting the polymer (A1) is preferably 10 mol % and more preferably 20 mol %. The upper limit of the proportion is preferably 50 mol %, and more preferably 40 mol %.

### Structural Unit (IV)

The structural unit (IV) is a structural unit that includes a lactone structure, a cyclic carbonate structure, a sultone structure, or a combination thereof.

Examples of the structural unit (IV) include structural units represented by the following formulae, and the like.

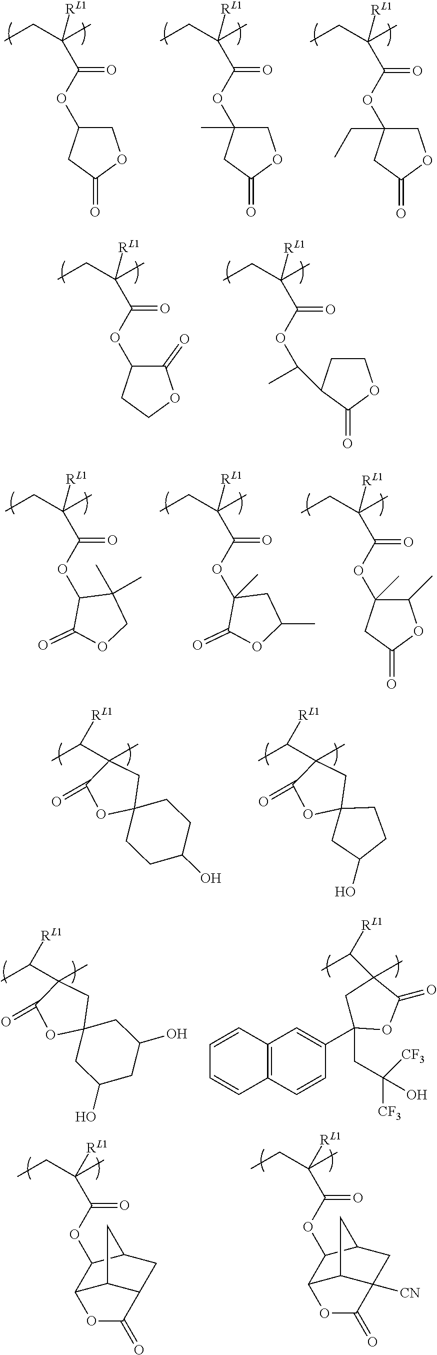

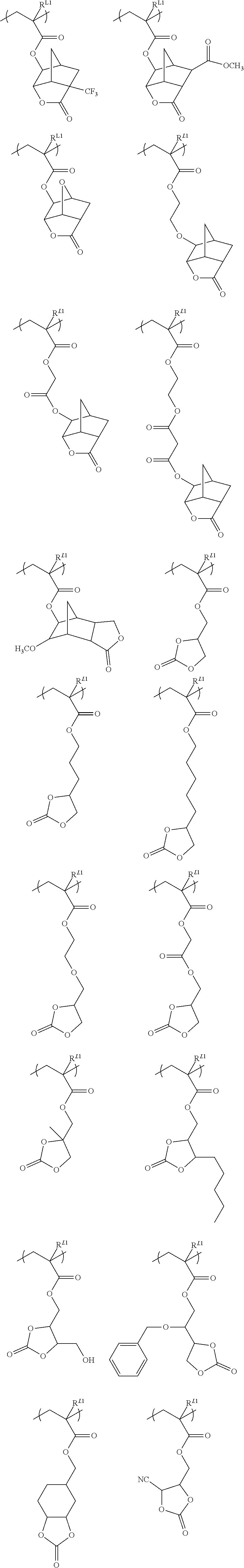

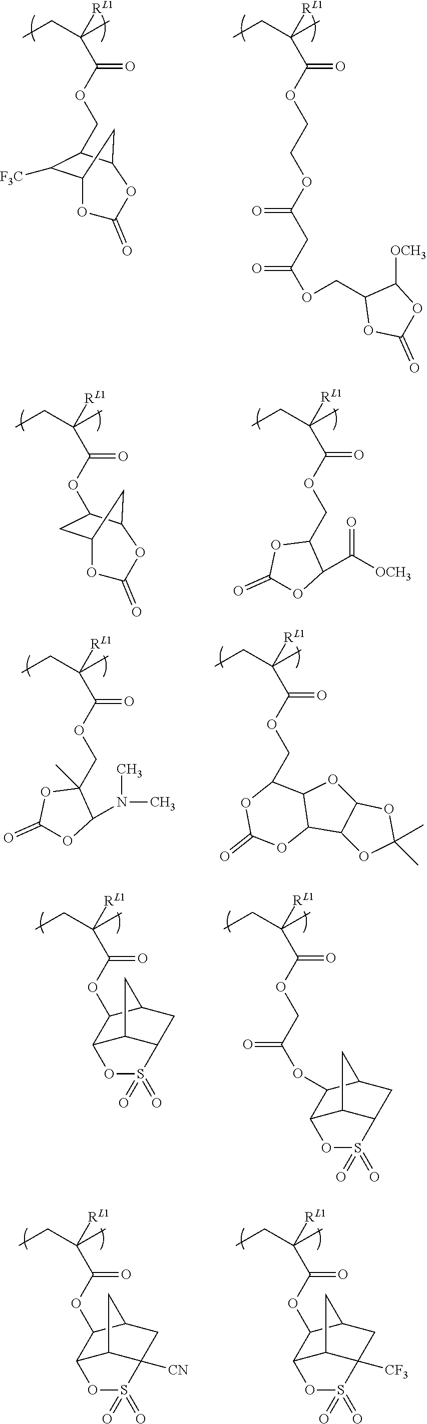

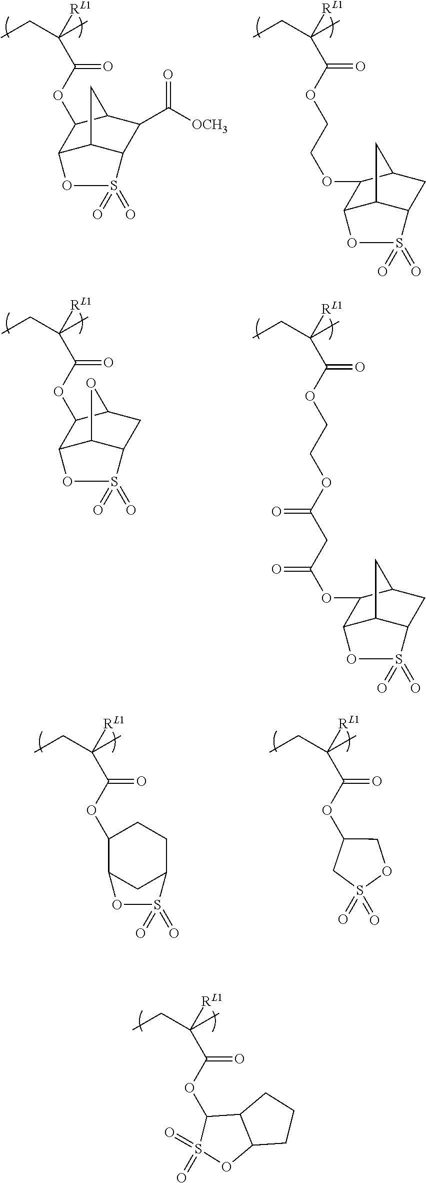

In the above formulae, R^{L1} represents a hydrogen atom, a fluorine atom, a methyl group, or a trifluoromethyl group.

The structural unit (IV) preferably includes a lactone structure, a sultone structure, or a combination thereof.

In the case in which the polymer (A1) has the structural unit (IV), the lower limit of a proportion of the structural unit (IV) contained with respect to the total structural units constituting the polymer (A1) is preferably 5 mol % and more preferably 10 mol %. The upper limit of the proportion is preferably 30 mol %, and more preferably 20 mol %.

### Structural Unit (V)

The structural unit (V) is a structural unit that includes an alcoholic hydroxy group. When the polymer (A1) further has the structural unit (V), the solubility of the polymer (A1) in a developer solution can be even further appropriately adjusted. The polymer (A1) may have one, or two or more types of the structural unit (V).

Examples of the structural unit (V) include structural units represented by the following formulae, and the like.

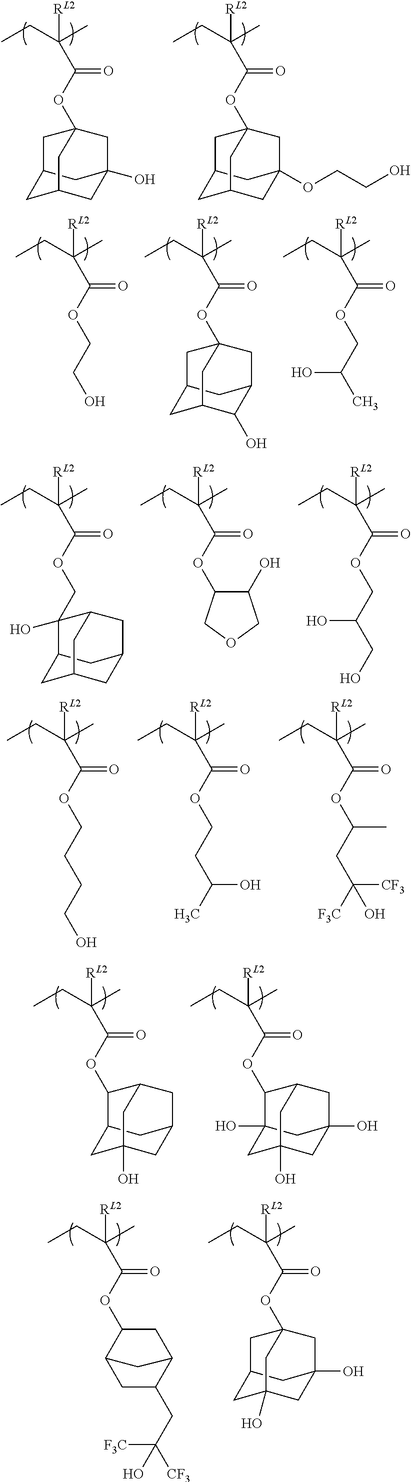

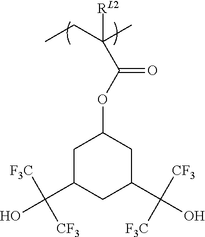

In the above formulae, R^{L2} represents a hydrogen atom, a fluorine atom, a methyl group, or a trifluoromethyl group.

In the case in which the polymer (A1) has the structural unit (V), the lower limit of a proportion of the structural unit (V) contained with respect to the total structural units constituting the polymer (A1) is preferably 5 mol % and more preferably 15 mol %. The upper limit of the proportion is preferably 30 mol %, and more preferably 20 mol %.

### (Z) Compound

The compound (Z) is represented by the following formula (2). The composition (I) may contain one, or two or more types of the compound (Z).

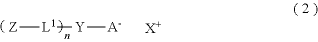

In the formula (2), Z represents an acid-labile group; L¹ represents *—O—CO— or —O—, wherein * denotes a site bonding to Z; Y represents an organic group having 1 to 30 carbon atoms and having a valency of (n+1), the organic group not containing a cyclic acetal structure; n is an integer of 1 to 5, wherein in a case in which n is no less than 2, two or more Zs are identical or different from each other, and two or more L¹s are identical or different from each other; A⁻ represents a monovalent anion group; and X⁺ represents a monovalent radiation-sensitive onium cation.

Hereinafter, the structure represented by (Z-L¹)ₙ-Y-A⁻ in the above formula (2) may be also referred to as “anion moiety”, and the structure represented by X⁺ in the above formula (2) may be also referred to as “cation moiety”. Furthermore, Z in the above formula (2) may be also referred to as “acid-labile group (z)”, Y in the above formula (2) may be also referred to as “skeletal structure (Y)”, and A⁻ in the above formula (2) may be also referred to as “anion group”.

In accordance with the type of the anion group, the compound (Z) has: an effect of generating an acid upon irradiation with a radioactive ray in the composition (I); or an effect of inhibiting an undesired chemical reaction (for example, a dissociation reaction of the acid-labile group) in light-unexposed regions by controlling a phenomenon in which an acid generated from the acid generating agent (B) and/or the like upon exposure is diffused in the resist film. In other words, in accordance with the type of the anion group, the compound (Z) functions as a radiation-sensitive acid generating agent or an acid diffusion control agent (quencher) in the composition (I).

In the case in which the compound (Z) functions as the radiation-sensitive acid generating agent, the acid-labile group (a) included in the structural unit (I) which is contained in the polymer (A1), or the like is dissociated by an action of an acid generated from the compound (Z) upon irradiation with a radioactive ray, whereby a carboxy group and/or the like are/is generated to create a difference in solubility of the resist film in the developer solution between light-exposed regions and light-unexposed regions; accordingly, a resist pattern can be formed.

In the case in which the compound (Z) functions as the acid diffusion control agent, an acid is generated in the light-exposed regions to increase the solubility or insolubility of the polymer (A1) in the developer solution, and on the other hand, a superior acid-trapping function by the anion is exhibited, functioning as a quencher in the light-unexposed regions, whereby acid diffused from the light-exposed regions is trapped. Thus, the compound (Z) can enhance roughness at interfaces between the light-exposed regions and the light-unexposed regions, and improve the resolution by enhancing the contrast between the light-exposed regions and the light-unexposed regions.

Despite the aforementioned function of the compound (Z) in the composition (I), it is considered that the composition (I) containing the compound (Z) is a factor in the composition (I) exhibiting superiority in the ability to inhibit development defects.

In the case in which the compound (Z) functions as the radiation-sensitive acid generating agent, the lower limit of a content of the compound (Z) in the composition (I) with respect to 100 parts by mass of the polymer (A1) is preferably 1 part by mass, and more preferably 2 parts by mass. The upper limit of the content is preferably 10 parts by mass, and more preferably 5 parts by mass.

In the case in which the compound (Z) functions as the acid diffusion control agent, the lower limit of a proportion of the compound (Z) in the composition (I) with respect to 100 parts by mass of the polymer (A1) is preferably 1 part by mass, and more preferably 2 parts by mass. The upper limit of the content is preferably 10 parts by mass, and more preferably 5 parts by mass.

Each structure contained in the compound (Z) is described below.

### Anion Moiety

The anion moiety is the structure represented by (Z-L¹)ₙ-Y-A⁻ in the above formula (2). n is preferably 1 to 3, more preferably 1 or 2, and still more preferably 1.

### L¹

L¹ represents a group which bonds to each of the acid-labile group (z) and the skeletal structure (Y), each described later. In the case in which L¹ represents *—O—CO—, the acid-labile group (z) is dissociated to generate a carboxy group. In the case in which L¹ represents-O—, the acid-labile group (z) is dissociated to generate a hydroxy group.

### Acid-Labile Group (z)

The acid-labile group (z) is a group which bonds to L¹. The acid-labile group (z) is a group that substitutes for a hydrogen atom in a carboxy group or a hydroxy group, and is dissociated by an action of an acid to give a carboxy group or a hydroxy group. The compound (Z) having the acid-labile group (z) is considered to be one factor in the composition (I) exhibiting superiority in the ability to inhibit development defects.

Examples of the acid-labile group (z) include groups (hereinafter, may be also referred to as “acid-labile groups (z-1) to (z-3)”) represented by the following formulae (z-1) to (z-3), and the like.

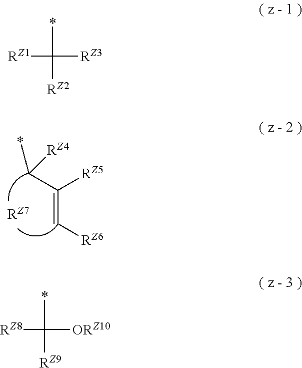

In the above formulae (z-1) to (z-3), * denotes a site that bonds to L¹ in the above formula (2).

In the above formula (z-1), R^{Z1} represents a monovalent hydrocarbon group having 1 to 20 carbon atoms; and R^{Z2} and R^{Z3} each independently represent a monovalent hydrocarbon group having 1 to 20 carbon atoms, or R^{Z2} and R^{Z3} taken together represent a saturated aliphatic ring having 3 to 20 ring atoms, together with the carbon atom to which R^{Z2} and R^{Z3} bond.

In the above formula (z-2), R^{Z4} represents a hydrogen atom; R^{Z5} and R^{Z6} each independently represent a hydrogen atom or a monovalent hydrocarbon group having 1 to 20 carbon atoms; and R⁷ represents a divalent hydrocarbon group having 1 to 20 carbon atoms constituting an unsaturated aliphatic ring having 4 to 20 ring atoms together with the carbon atoms to which R^{Z4}, R^{Z5}, and R^{Z6} respectively bond.

In the formula (z-3), R^{Z8} and R^{Z9} each independently represent a hydrogen atom or a monovalent hydrocarbon group having 1 to 20 carbon atoms, and R^{Z10} represents a monovalent hydrocarbon group having 1 to 20 carbon atoms, or R^{Z8} and R^{Z9} taken together represent an aliphatic ring having 3 to 20 ring atoms together with the carbon atom to which R^{Z8} and R^{Z9} bond, or R^{Z8} and R^{Z10} taken together represent an aliphatic heterocycle having 4 to 20 ring atoms together with the carbon atom to which R^{Z8} bonds and the oxygen atom to which R^{Z10} bonds.

Examples of the monovalent hydrocarbon group having 1 to 20 carbon atoms which may be represented by R^{Z1}, R^{Z2}, R^{Z3}, R^{Z5}, R^{Z6}, R^{Z8}, R^{Z9}, or R^{Z10} include groups similar to those exemplified in the above formula (3-1) as the monovalent hydrocarbon group having 1 to 20 carbon atoms, of the monovalent organic group having 1 to 20 carbon atoms which may be represented by R⁴, and the like.

Examples of the saturated aliphatic ring having 3 to 20 ring atoms which may be represented by R^{Z2} and R^{Z3} taken together, together with the carbon atom to which R^{Z2} and R^{Z3} bond, and the aliphatic ring having 3 to 20 ring atoms which may be constituted by R^{Z8} and R^{Z9} taken together, together with the carbon atom to which R^{Z8} and R^{Z9} bond, include structures similar to those exemplified in the explanation of the above formula (3-1).

Examples of the divalent hydrocarbon group having 1 to 20 carbon atoms represented by R^{Z7} include groups similar to those exemplified in the above formula (3-1) as the monovalent hydrocarbon group having 1 to 20 carbon atoms, of the monovalent organic group having 1 to 20 carbon atoms which may be represented by R⁴, and the like.

Examples of the unsaturated aliphatic ring having 4 to 20 ring atoms represented by R^{Z7}, together with the three carbon atoms to which R^{Z4}, R^{Z5}, and R^{Z6} respectively bond, include structures similar to those exemplified in the explanation of the above formula (III-2), and the like.

Examples of the aliphatic heterocycle having 4 to 20 ring atoms which may be represented by R^{Z8} and R^{Z10} taken together, together with the carbon atom to which R^{Z8} bonds and the oxygen atom to which R^{Z10} bonds, include structures similar to those exemplified in the explanation of the above formula (III-3), and the like.

A part or all of hydrogen atoms bonded to atoms constituting the hydrocarbon groups or the ring structures may be substituted with a substituent. Examples of the substituent include a monovalent heteroatom-containing group, a monovalent organic group having 1 to 20 carbon atoms, and the like. The monovalent heteroatom-containing group and the monovalent organic group having 1 to 20 carbon atoms are explained in relation to R⁴ in the above formula (3-1).

The substituent is preferably the halogen atom, a hydroxy group, the monovalent hydrocarbon group having 1 to 20 carbon atoms, the group (α) that contains a divalent heteroatom-containing group between a carbon-carbon bond of this hydrocarbon group, the group (β) obtained by substituting with a monovalent heteroatom-containing group a part or all of hydrogen atoms included in the monovalent hydrocarbon group or the group (α), or the group (γ) obtained by combining the monovalent hydrocarbon group, the group (α), or the group (β) with a divalent heteroatom-containing group.

Furthermore, the substituent is also preferably a monovalent group containing the acid-labile group (z).

R^{Z1} represents preferably the chain hydrocarbon group, more preferably an alkyl group, and still more preferably a methyl group, an ethyl group, an i-propyl group, or a tert-butyl group.

In the case in which R^{Z2} and R^{Z3} each represent the monovalent hydrocarbon group having 1 to 20 carbon atoms, R^{Z2} and R^{Z3} each represent preferably the chain hydrocarbon group, the alicyclic hydrocarbon group, or the aromatic hydrocarbon group, more preferably an alkyl group, the monocyclic alicyclic saturated hydrocarbon group, the polycyclic alicyclic saturated hydrocarbon group, or an aryl group, and still more preferably a methyl group, an ethyl group, an i-propyl group, a cyclopentyl group, a cyclohexyl group, a norbornyl group, an adamantyl group, or a phenyl group.

In the case in which R^{Z2} and R^{Z3} taken together represent the saturated aliphatic ring having 3 to 20 ring atoms together with the carbon atom to which R^{Z2} and R^{Z3} bond, the saturated aliphatic ring is preferably the monocyclic saturated aliphatic ring or the polycyclic saturated aliphatic ring, more preferably a cyclopentane ring, a cyclohexane ring, a norbornane ring, an adamantane ring, a tricyclodecane ring, or a tetracyclododecane ring.

R^{Z5} represents preferably a hydrogen atom.

R^{Z6} represents preferably a hydrogen atom or the chain hydrocarbon group, more preferably a hydrogen atom or an alkyl group, and still more preferably a hydrogen atom or a methyl group.

The unsaturated aliphatic ring having 4 to 20 ring atoms which is represented by R^{Z7}, together with the three carbon atoms to which R^{Z4}, R^{Z5}, and R^{Z6} respectively bond, is preferably the monocyclic unsaturated aliphatic ring, and more preferably a cyclopentene ring or a cyclohexene ring.

The case in which R^{Z8} and R^{Z9} each represent a hydrogen atom or the substituted or unsubstituted monovalent hydrocarbon group having 1 to 20 carbon atoms, and R^{Z10} represents the substituted or unsubstituted monovalent hydrocarbon group having 1 to 20 carbon atoms is explained. R^{Z8} and R^{Z9} in this case are each preferably a hydrogen atom or the chain hydrocarbon group, and more preferably a hydrogen atom or an alkyl group. R^{Z10} in this case is preferably the chain hydrocarbon group or the alicyclic hydrocarbon group, and more preferably a methyl group, an ethyl group, an adamantyl group, or a tricyclododecyl group.

The case in which R^{Z8} and R^{Z10} taken together represent the substituted or unsubstituted aliphatic heterocycle having 4 to 20 ring atoms, together with the carbon atom to which R^{Z8} bonds and the oxygen atom to which R^{Z10} bonds, is explained. The aliphatic heterocycle in this case is preferably an oxacyclohexane structure.

The acid-labile group (z) is preferably the acid-labile group (z-1) or (z-3).

Examples of the acid-labile group (z-1) include groups (hereinafter, may be also referred to as “acid-labile groups (z-1-1) to (z-1-26)”) represented by the following formulae (z-1-1) to (z-1-26), and the like.

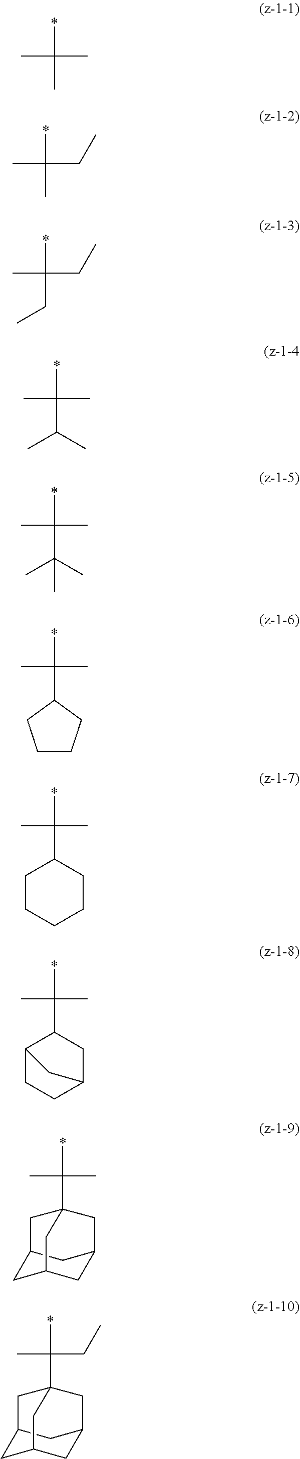

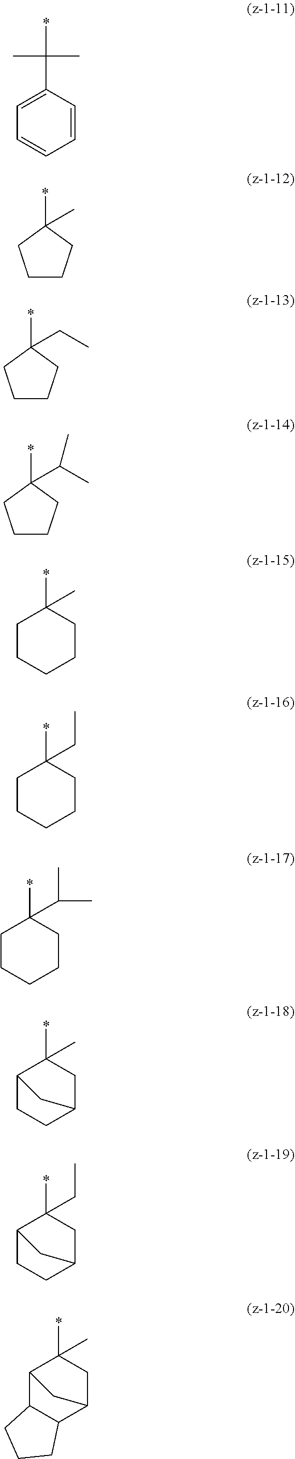

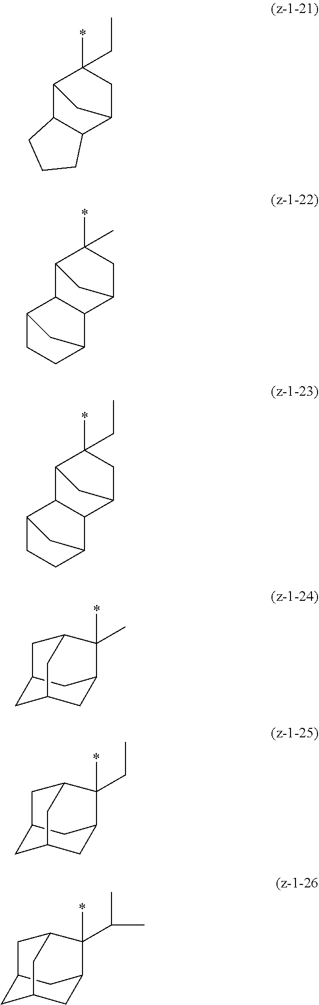 [SMILES: *C1(CC)CC2CC1C1CCCC21 ; *C1(C)CC2CC1C1C3CCC(C3)C21 ; *C1(CC)CC2CC1C1C3CCC(C3)C21 ; *C1(C)C2CC3CC(C2)CC1C3 ; *C1(CC)C2CC3CC(C2)CC1C3 ; *C1(C(C)C)C2CC3CC(C2)CC1C3]

In the above formulae (z-1-1) to (z-1-26), * is as defined in the above formula (z-1).

Examples of the acid-labile group (z-3) include groups represented by the following formulae (z-3-1) to (z-3-11), and the like.

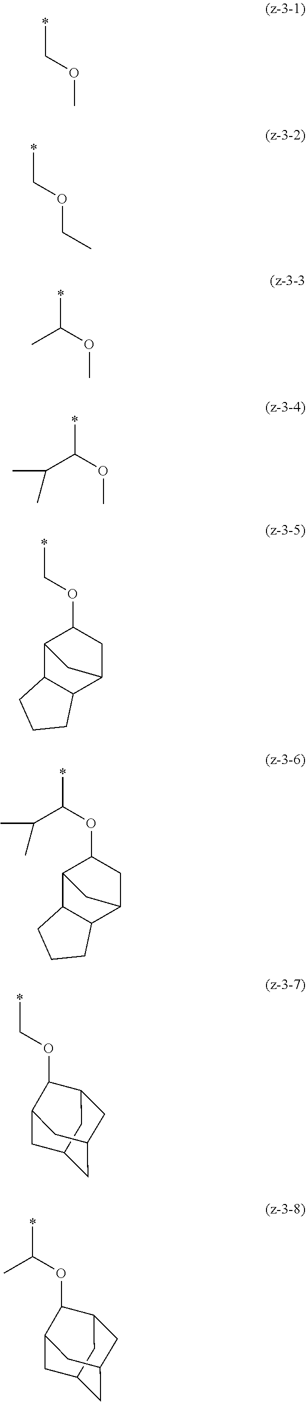

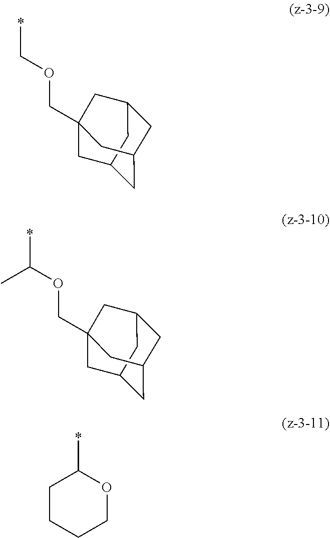 [SMILES: *COCC12CC3CC(CC(C3)C1)C2 ; *C(C)OCC12CC3CC(CC(C3)C1)C2 ; *C1CCCCO1]

In the above formulae (z-3-1) to (z-3-11), * is as defined in the above formula (z-3).

### Skeletal Structure (Y)

The skeletal structure (Y) is an organic group having 1 to 30 carbon atoms and having a valency of (n+1), the organic group not containing a cyclic acetal structure. The “cyclic acetal structure” encompasses not only a monocyclic cyclic acetal structure, but also a polycyclic cyclic acetal structure. The polycyclic cyclic acetal structure encompasses, for example, a spiro-type polycyclic ring in which a monocyclic cyclic acetal structure such as a dioxolane ring and an aliphatic hydrocarbon ring such as a cyclohexane ring have one shared atom, and a fused polycyclic ring in which the above-mentioned two rings have two shared atoms.

The organic group having 1 to 30 carbon atoms, having a valency of (n+1), and not containing a cyclic acetal structure is exemplified by: a monovalent hydrocarbon group having 1 to 30 carbon atoms; a group (α) that contains a divalent heteroatom-containing group between a carbon-carbon bond of this monovalent hydrocarbon group; a group (β) obtained by substituting with a monovalent heteroatom-containing group, a part or all of hydrogen atoms included in the monovalent hydrocarbon group or the group (α); a group (γ) obtained by combining the monovalent hydrocarbon group, the group (α), or the group (β) with a divalent heteroatom-containing group; and the like. Examples of the divalent heteroatom-containing group and the monovalent heteroatom-containing group include groups similar to those exemplified in the explanation of the monovalent organic group having 1 to 20 carbon atoms which may be represented by R⁴ in the above formula (3-1), and the like.

The skeletal structure (Y) preferably contains, as a ring structure, only an aliphatic hydrocarbon ring, an aromatic hydrocarbon ring, an aromatic heterocycle, or a combination thereof. In other words, the skeletal structure (Y) does not contain, in the structure thereof, a ring structure other than an aliphatic hydrocarbon ring, an aromatic hydrocarbon ring, an aromatic heterocycle, or a combination thereof. The “combination thereof” encompasses not only a case in which two or more of the ring structures are directly bonded, but also a case in which the ring structures are bonded via a divalent linking group, explained later.

Examples of the aliphatic hydrocarbon ring include structures similar to those exemplified as the aliphatic hydrocarbon ring having 3 to 30 ring atoms which gives R² in the above formula (1), and the like. Of these, the monocyclic saturated aliphatic ring, the polycyclic saturated aliphatic ring, or the polycyclic unsaturated aliphatic ring is preferred, and a cyclohexane ring, an adamantane ring, or a norbornene ring is more preferred.

Examples of the aromatic hydrocarbon ring include structures similar to those exemplified as the aromatic hydrocarbon ring having 6 to 30 ring atoms which gives Ar¹ in the above formula (1), and the like. Of these, a benzene ring or a naphthalene ring is preferred.

Examples of the aromatic heterocycle include: oxygen atom-containing heterocycles such as a furan ring, a pyran ring, a benzofuran ring, and a benzopyran ring; nitrogen atom-containing heterocycles such as a pyridine ring, a pyrimidine ring, and an indole ring; sulfur atom-containing heterocycles such as a thiophene ring and a dibenzothiophene ring; and the like.

A part or all of hydrogen atoms bonded to atoms constituting the ring structures may be substituted with a substituent. Examples of the substituent include a monovalent heteroatom-containing group, a monovalent organic group having 1 to 20 carbon atoms, and the like. The monovalent heteroatom-containing group and the monovalent organic group having 1 to 20 carbon atoms are explained in relation to R⁴ in the above formula (3-1).

The substituent is explained as the substituent in the hydrocarbon group represented by R^{Z1} in the above formula (z-1).

The skeletal structure (Y) preferably further has a divalent chain hydrocarbon group having 1 to 10 carbon atoms or a group (hereinafter, may be also referred to as “fluorinated chain hydrocarbon group”) obtained by substituting a part or all of hydrogen atoms contained in this chain hydrocarbon group with a fluorine atom. Furthermore, the chain hydrocarbon group or the fluorinated chain hydrocarbon group preferably bonds to the anion group.

In the skeletal structure (Y), the ring structure may be directly bonded to the chain hydrocarbon group or the fluorinated chain hydrocarbon group, or may be bonded thereto via a divalent linking group.

Examples of the divalent linking group include a carbonyl group, an ether group, a sulfide group, an alkanediyl group having 1 to 10 carbon atoms, a group obtained by a combination thereof, or the like.

Examples of the skeletal structure (Y) include a group having a valency of (n+1) which is represented by the following formula (Y-1).

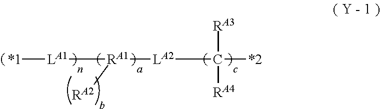

In the above formula (Y-1), R^{A1} represents a group obtained by removing (n+b+1) hydrogen atoms from a ring structure other than the cyclic acetal structure; a is an integer of 0 to 1; R^{A2} is a halogen atom, a hydroxy group, a carboxy group, a cyano group, a nitro group, or a monovalent organic group having 1 to 10 carbon atoms; b is an integer of 0 to 5, wherein in a case in which a is 0, b is also 0, and in a case in which b is no less than 2, a plurality of R^{A2}s are identical or different from each other; L^{A1} and L^{A2} are each a single bond or the divalent linking group; n is identical to n in the above formula (2); R^{A3} and R^{A4} each independently represent a hydrogen atom, a fluorine atom, a monovalent hydrocarbon group having 1 to 20 carbon atoms, or a monovalent fluorinated hydrocarbon group having 1 to 20 carbon atoms; c is an integer of 1 to 10, wherein in a case in which c is no less than 2, a plurality of R^{A3}s are identical or different from each other and a plurality of R^{A4}s are identical or different from each other; *1 denotes a site bonding to L¹ in the above formula (2); and *2 denotes a site bonding to A⁻ in the above formula (2).

Examples of the ring structure, other than the cyclic acetal structure, which gives R^{A1} include the aliphatic hydrocarbon ring, the aromatic hydrocarbon ring, and the aromatic heterocycle, each described above, as well as an aliphatic heterocycle other than a cyclic acetal, and a combination thereof. Of these, an adamantane ring or a benzene ring is preferred.

In the case in which a is 0, the basic skeleton (Y) does not contain a ring structure, and has a chain structure.

R^{A2} represents preferably an iodine atom.

b is preferably 0 to 2.

L^{A2} and L^{A2} are each preferably a single bond, an ether group, or a carbonyloxy group.

c is preferably 1 to 3, and more preferably 1 or 2.

### Anion Group

The anion group is a group which bonds to the above-described skeletal structure (Y). The anion group is preferably a monovalent organic acid anion group, and more preferably a sulfonate group (—SO₃⁻) or a carboxylate group (—COO⁻).

As described above, in accordance with the type of the anion group, the compound (Z) functions as the radiation-sensitive acid generating agent or the acid diffusion control agent (quencher) in the composition (I).

In the case in which the anion group is a sulfonate group, the compound (Z) functions as the radiation-sensitive acid generating agent in the composition (I). In this case, the composition (I) preferably contains the acid diffusion control agent (C). Furthermore, in this case, the composition (I) may contain an acid generating agent (the acid generating agent (B)) other than the compound (Z).

In the case in which the anion group is a carboxylate group, the compound (Z) functions as the acid diffusion control agent in the composition (I). In this case, the composition (I) preferably contains the acid generating agent (B). Furthermore, in this case, the composition (I) may contain an acid diffusion control agent (the acid diffusion control agent (C)) other than the compound (Z).

Examples of the anion moiety in the case in which the anion group is a sulfonate group include partial structures represented by the following formulae (A-1-1) to (A-1-3).

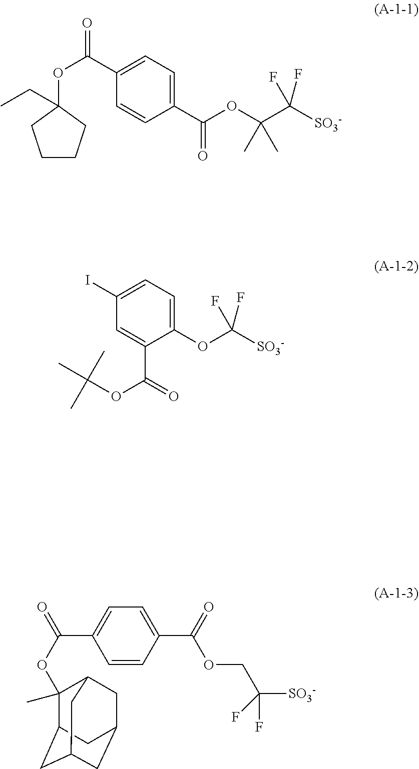

Examples of the anion moiety in the case in which the anion group is a carboxylate group include partial structures represented by the following formulae (A-2-1) to (A-2-4).

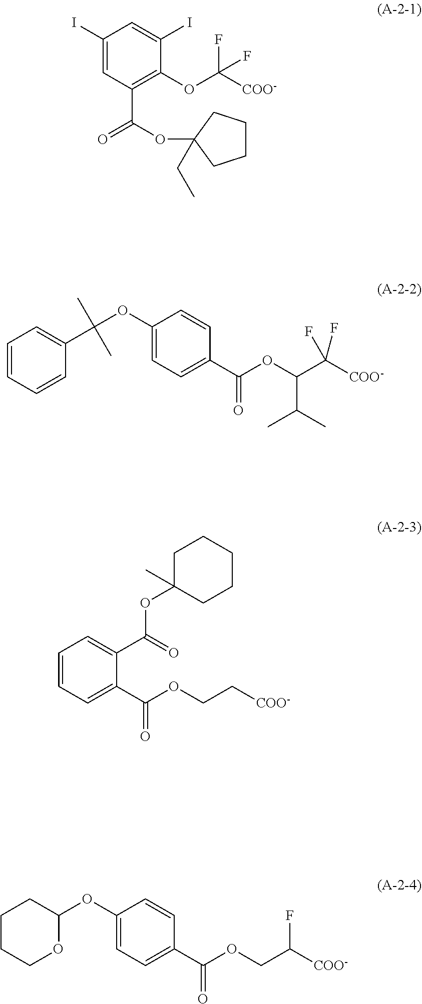

### Cation Moiety

Examples of the monovalent radiation-sensitive onium cation represented by X⁺ include monovalent cations (hereinafter, may be also referred to as “cations (r-a) to (r-c)”) represented by the following formulae (r-a) to (r-c), and the like.

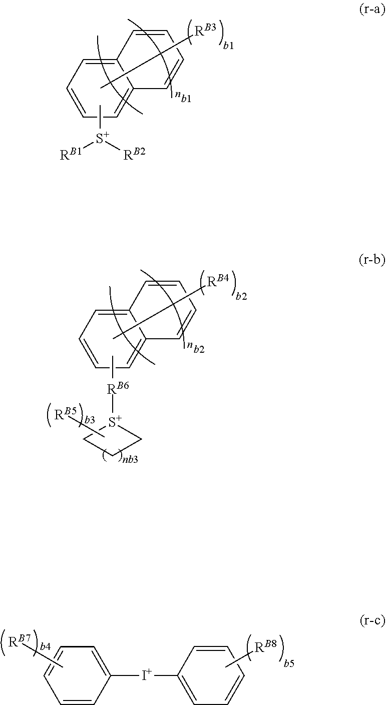

In the above formula (r-a), R^{B1} and R^{B2} each independently represent a group obtained by removing one hydrogen atom from a substituted or unsubstituted aromatic hydrocarbon ring having 6 to 20 ring atoms, or R^{B1} and R^{B2} taken together represent a substituted or unsubstituted polycyclic aromatic ring having 9 to 30 ring atoms, together with the sulfur atom to which R^{B1} and R^{B2} bond; R^{B3} represents a halogen atom, a hydroxy group, a nitro group, or a monovalent organic group having 1 to 20 carbon atoms; b1 is an integer of 0 to 9, wherein in a case in which b1 is no less than 2, a plurality of R^{B3}s are identical or different from each other; and n_{b1} is an integer of 0 to 3.

In the above formula (r-b), R^{B4} and R^{B5} each independently represent a halogen atom, a hydroxy group, a nitro group, or a monovalent organic group having 1 to 20 carbon atoms; b2 is an integer of 0 to 9, wherein in a case in which b2 is no less than 2, a plurality of R^{B4}s are identical or different from each other; b3 is an integer of 0 to 10, wherein in a case in which b3 is no less than 2, a plurality of R^{B5}s are identical or different from each other, and each R^{B5} represents a halogen atom, a hydroxy group, a nitro group, or a monovalent organic group having 1 to 20 carbon atoms; R^{B6} represents a single bond or a divalent organic group having 1 to 20 carbon atoms; n_{b2} is an integer of 0 to 2; and n_{b3} is an integer of 0 to 3.

In the above formula (r-c), R^{B7} and R^{B8} each independently represent a halogen atom, a hydroxy group, a nitro group, or a monovalent organic group having 1 to 20 carbon atoms; b4 is an integer of 0 to 5, wherein in a case in which b4 is no less than 2, a plurality of R^{B7}s are identical or different from each other; and b5 is an integer of 0 to 5, wherein in a case in which b5 is no less than 2, a plurality of R^{B8}s are identical or different from each other.

In the case in which R^{B1} and R^{B2} each represent the group obtained by removing one hydrogen atom from a substituted or unsubstituted aromatic hydrocarbon ring having 6 to 20 ring atoms, examples of the aromatic hydrocarbon ring include the structures having 6 to 20 ring atoms, of the structures exemplified as the aromatic hydrocarbon ring having 6 to 30 ring atoms which give A^{r1} in the above formula (1), and the like. Of these, a benzene ring is preferred.

In the case in which R^{B1} and R^{B2} taken together represent a polycyclic aromatic ring having 9 to 30 ring atoms, together with the sulfur atom to which R^{B1} and R^{B2} bond, examples of the polycyclic aromatic ring include a benzothiophene ring, a dibenzothiophene ring, a thioxanthene ring, a thiaxanthon ring, a phenoxathiin ring, and the like.

A part or all of hydrogen atoms bonded to atoms constituting the aromatic hydrocarbon ring or the polycyclic aromatic ring may be substituted with a substituent. Examples of the substituent include substituents similar to those exemplified as the substituent which may be contained in the aliphatic hydrocarbon ring which gives R¹ in the above formula (1), and the like. Of these, a fluorine atom, an alkyl group, or a fluorinated alkyl group is preferred, a fluorine atom, a methyl group, a tert-butyl group, or a trifluoromethyl group is more preferred, and a fluorine atom or a trifluoromethyl group is still more preferred.

Examples of the monovalent organic group having 1 to 20 carbon atoms which may be represented by each of R^{B3}, R^{B4}, R^{B5}, R^{B7}, and R^{B8} include groups similar to the groups exemplified as the monovalent organic group having 1 to 20 carbon atoms which may be represented by R⁴ in the above formula (3-1), and the like.

R^{B3}, R^{B4}, R^{B5}, R^{B7}, and R^{B8} each represent preferably a fluorine atom, an alkyl group, or a fluorinated alkyl group, more preferably a fluorine atom, a methyl group, a tert-butyl group, or a trifluoromethyl group, and still more preferably a fluorine atom or a trifluoromethyl group.

b1 is preferably 0 to 3 and more preferably 0 to 2. n_{b1} is preferably 0 or 1. In a case in which b1 is no less than 1 and n_{b1} is 0, at least one R^{B3} preferably bonds at a position para to the sulfur atom.

b2 is preferably 0 to 3 and more preferably 0 to 2. n_{b2} is preferably 0 or 1. In a case in which b2 is no less than 1 and n_{b2} is 0, at least one R^{B4} preferably bonds at a position para to the sulfur atom.

b3 is preferably 0 to 2, and more preferably 0 or 1. n_{b3} is preferably 2 or 3.

b4 is preferably 0 to 2, and more preferably 0 or 1. In a case in which b4 is no less than 1, at least one R^{B7} preferably bonds at a position para to the iodine atom. b5 is preferably 0 to 2, and more preferably 0 or 1. In a case in which b5 is no less than 1, at least one R^{B8} preferably bonds at a position para to the iodine atom.

Examples of the divalent organic group which may be represented by R^{B6} include groups obtained by removing one hydrogen atom from the groups exemplified as the monovalent organic group having 1 to 20 carbon atoms which may be represented by R⁴ in the above formula (3-1).

R^{B6} represents preferably a single bond.

The monovalent radiation-sensitive onium cation represented by X⁺ is preferably the cation (r-a) or the cation (r-c).

The cation (r-a) is preferably a cation represented by the following formulae (r-a-1) to (r-a-9).

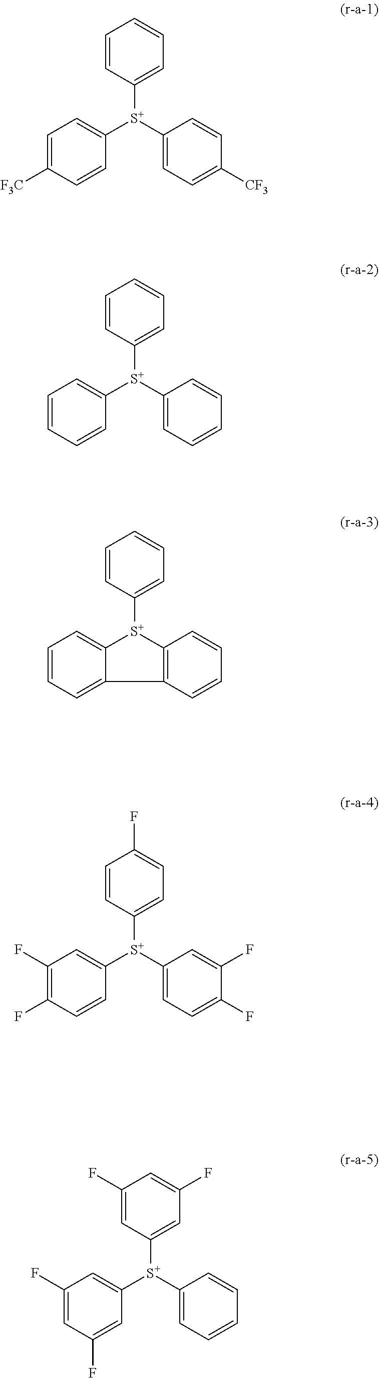 [SMILES: FC(F)(F)c1ccc([S+](c2ccccc2)c2ccc(C(F)(F)F)cc2)cc1 ; c1ccc([S+](c2ccccc2)c2ccccc2)cc1 ; c1ccc(-[s+]2c3ccccc3c3ccccc32)cc1 ; Fc1ccc([S+](c2ccc(F)c(F)c2)c2ccc(F)c(F)c2)cc1 ; Fc1cc(F)cc([S+](c2ccccc2)c2cc(F)cc(F)c2)c1]

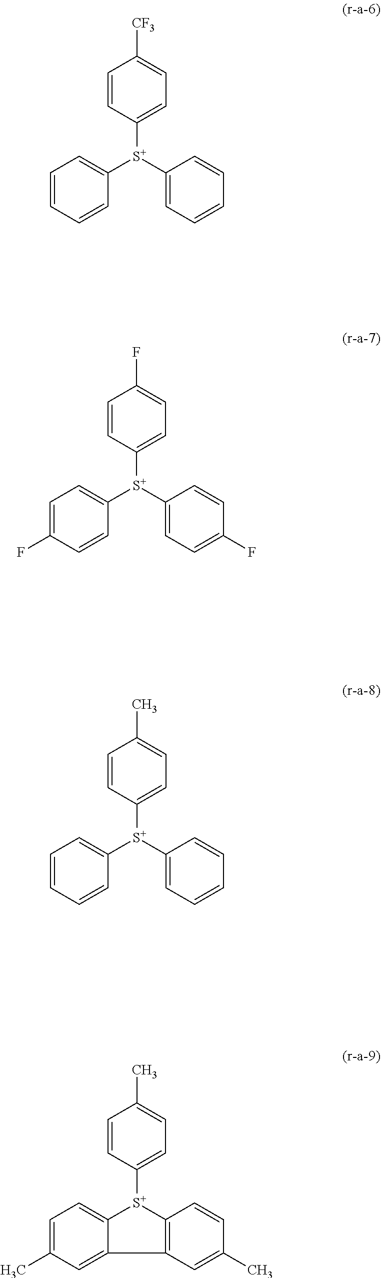

The cation (r-c) is preferably a cation represented by the following formulae (r-c-1) to (r-c-4).

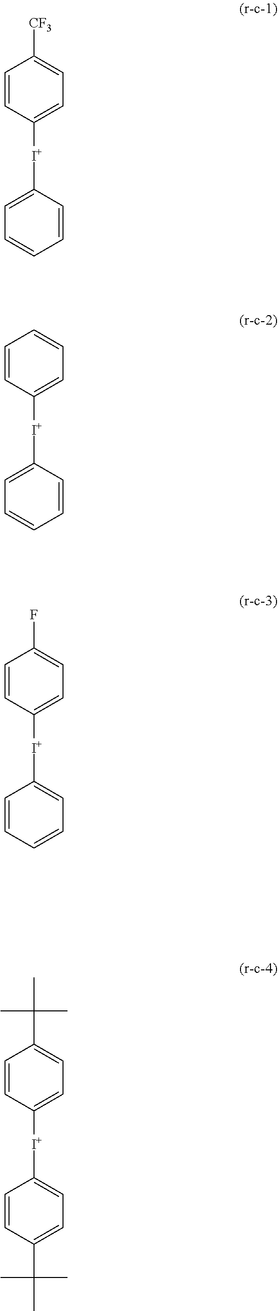 [SMILES: FC(F)(F)c1ccc([I+]c2ccccc2)cc1 ; c1ccc([I+]c2ccccc2)cc1 ; Fc1ccc([I+]c2ccccc2)cc1 ; CC(C)(C)c1ccc([I+]c2ccc(C(C)(C)C)cc2)cc1]

As the compound (Z), a compound obtained by appropriately combining the anion moiety with the cation moiety can be used.

### (B) Acid Generating Agent

The acid generating agent (B) is a radiation-sensitive acid generating agent other than the compound (Z). The acid generating agent (B) is a compound which generates an acid by irradiation with a radioactive ray. In the case in which the compound (Z) contained in the composition (I) functions as the acid diffusion control agent, the composition (I) preferably contains the acid generating agent (B). In this case, the acid-labile group (a) included in the structural unit (I) which is contained in the polymer (A1), or the like is dissociated by an action of an acid generated from the acid generating agent (B) upon irradiation with a radioactive ray, whereby a carboxy group and/or the like are/is generated to create a difference in solubility of the resist film in the developer solution between light-exposed regions and light-unexposed regions; accordingly, a resist pattern can be formed. The composition (I) may contain one, or two or more types of the acid generating agent (B).

The acid generating agent (B) can be used without particular limitation as long as it is a compound which does not fall under the compound (Z), and is a compound which can be used as a radiation-sensitive acid generating agent. The acid generating agent (B) is exemplified by an onium salt compound, an N-sulfonyloxyimide compound, a sulfonimide compound, a halogen-containing compound, a diazoketone compound, and the like. Furthermore, specific examples of the acid generating agent (B) include compounds disclosed in paragraphs [0080] to [0113] of Japanese Unexamined Patent Application, Publication No. 2009-134088, and the like.

The acid generating agent (B) is preferably an onium salt compound, more preferably a compound containing a radiation-sensitive onium cation moiety and an anion moiety of a strong acid, and still more preferably a compound containing a radiation-sensitive onium cation moiety and an anion moiety of sulfonic acid. In other words, the acid generating agent (B) is more preferably a compound which generates a strong acid by an exposure, and still more preferably a compound which generates sulfonic acid by an exposure.

Examples of the radiation-sensitive onium cation include cations similar to those exemplified as the monovalent radiation-sensitive onium cation in the section “(Z) Compound”.

Examples of the anion moiety of a strong acid include anion moieties including a sulfonate anion as an anion group, and the like.

The anion moiety preferably further has a ring structure. The ring structure is preferably a ring structure having 5 or more ring atoms.

The ring structure having 5 or more ring atoms is exemplified by an aliphatic ring having 5 or more ring atoms, an aliphatic heterocycle having 5 or more ring atoms, an aromatic hydrocarbon ring having 5 or more ring atoms, an aromatic heterocycle having 5 or more ring atoms, or a combination thereof.

The lower limit of the number of ring atoms in the ring structure is preferably 6, more preferably 8, still more preferably 9, and particularly preferably 10. The upper limit of the number of ring atoms is preferably 25.

In the case in which the ring structure having 5 or more ring atoms is an aromatic hydrocarbon ring, a part or all of hydrogen atoms bonding to carbon atoms constituting the ring structure are preferably substituted with an iodine atom. The number of substitutions with an iodine atom in this case is preferably 1 to 4, and more preferably 1 to 3. The aromatic hydrocarbon ring is preferably a benzene ring or a naphthalene ring, and more preferably a benzene ring.

As described above, the acid generating agent (B) is a compound which is different from the compound (Z). Thus, the anion moiety preferably does not have the above-described acid-labile group (z).

A compound obtained by appropriately combining the radiation-sensitive onium cation moiety with the anion moiety of a strong acid can be used as the acid generating agent (B)

The acid generating agent (B) is preferably a compound represented by the following formulae (B-1) to (B-6).

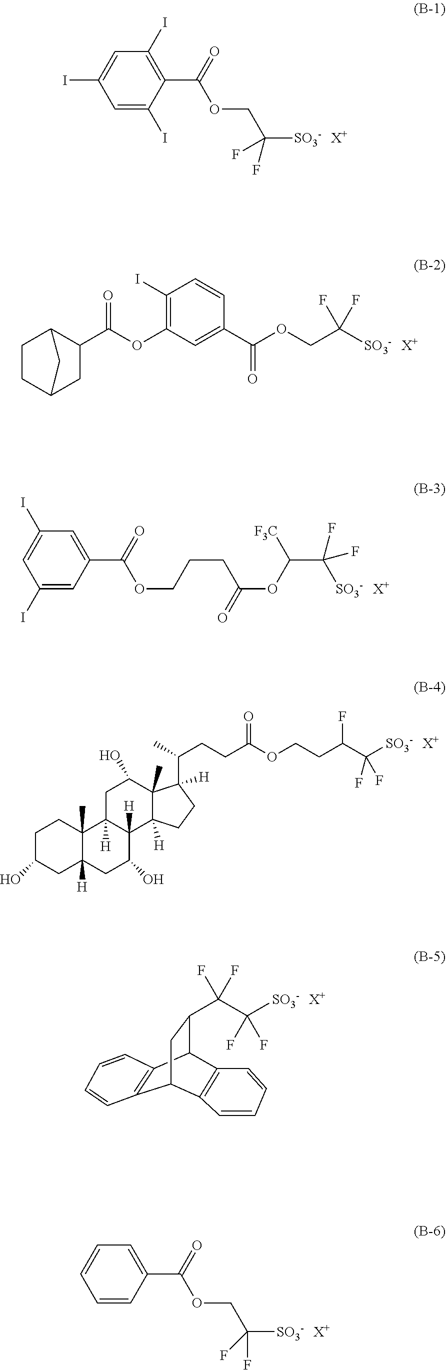

In the above formulae (B-1) to (B-6), X⁺ represents a monovalent radiation-sensitive onium cation.

In the case in which the composition (I) contains the acid generating agent (B), the lower limit of a content of the acid generating agent (B) in the composition (I) with respect to 100 parts by mass of the polymer (A1) is preferably 1 part by mass, more preferably 2 parts by mass, and still more preferably 3 parts by mass. The upper limit of the content is preferably 30 parts by mass, more preferably 20 parts by mass, and still more preferably 10 parts by mass.

### (C) Acid Diffusion Control Agent

The acid diffusion control agent (C) is an acid diffusion control agent other than the compound (Z). In particular, in the case in which the compound (Z) contained in the composition (I) functions as the radiation-sensitive acid generating agent, the composition (I) preferably contains the acid diffusion control agent (C). In this case, the acid diffusion control agent (C) is able to control a diffusion phenomenon, in the resist film, of the acid generated from the compound (Z) upon exposure, thereby serving to inhibit unwanted chemical reactions in light-unexposed regions. The composition (I) may contain one, or two or more types of the acid diffusion control agent (C).

Examples of the acid diffusion control agent (C) include a nitrogen atom-containing compound, a compound (hereinafter, may be also referred to as “photodegradable base”) that is photosensitized by an exposure to generate a weak acid, and the like. The acid diffusion control agent (C) is preferably the photodegradable base.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl) morpholine, and N-t-pentyloxycarbonyl-4-hydroxypiperidine; and the like.

The photodegradable base is exemplified by a compound containing a radiation-sensitive onium cation moiety and an anion moiety of a weak acid, and the like. The photodegradable base generates a weak acid in light-exposed regions and increases solubility or insolubility of the polymer (A1) in the developer solution, and consequently roughness of surfaces of the light-exposed regions after development is suppressed. On the other hand, the photodegradable base exerts a superior acid-capturing function due to an anion in light-unexposed regions and serves as a quencher, and thus captures the acid diffused from the light-exposed regions. In other words, since the photodegradable base serves as a quencher only at the light-unexposed regions, the contrast resulting from a deprotection reaction of the acid-labile group is improved, and consequently the resolution can be improved.

Examples of the radiation-sensitive onium cation moiety include cations similar to those exemplified as the monovalent radiation-sensitive onium cation in the section “(Z) Compound”.

Examples of the anion moiety of a weak acid include anion moieties which contain a carboxylate anion (—COO⁻) as the anion group, and the like.

As described above, the acid diffusion control agent (C) is a compound which is different from the compound (Z). Thus, the anion moiety preferably does not have the above-described acid-labile group (z).

A compound obtained by appropriately combining the radiation-sensitive onium cation moiety and the anion moiety of a weak acid can be used as the photodegradable base.

The acid diffusion control agent (C) is preferably a compound represented by the following formulae (C-1) to (C-5).

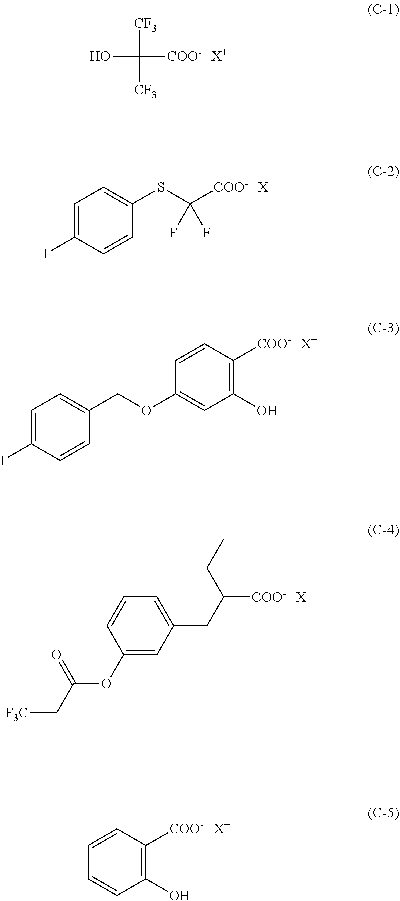

In the above formulae (C-1) to (C-5), X⁺ represents a monovalent radiation-sensitive onium cation.

In the case in which the composition (I) contains the acid diffusion control agent (C), the lower limit of a proportion of the acid diffusion control agent (C) in the composition (I) with respect to 100 parts by mass of the polymer (A1) is preferably 1 part by mass, and more preferably 2 parts by mass. The upper limit of the content is preferably 10 parts by mass, and more preferably 5 parts by mass.

### (D) Organic Solvent

The composition (I) typically contains the organic solvent (D). The organic solvent (D) is not particularly limited as long as it is a solvent capable of dissolving or dispersing at least the polymer (A1) and the compound (Z), as well as the acid generating agent (B), the acid diffusion control agent (C), and the other optional component(s) which is/are contained as needed.

The organic solvent (D) is exemplified by an alcohol solvent, an ether solvent, a ketone solvent, an amide solvent, an ester solvent, a hydrocarbon solvent, and the like. The composition (I) may contain one, or two or more types of the organic solvent (D).

Examples of the alcohol solvent include:
aliphatic monohydric alcohol solvents having 1 to 18 carbon atoms such as 4-methyl-2-pentanol, n-hexanol, and diacetone alcohol;
alicyclic monohydric alcohol solvents having 3 to 18 carbon atoms such as cyclohexanol;
polyhydric alcohol solvents having 2 to 18 carbon atoms such as 1,2-propylene glycol;
polyhydric alcohol partial ether solvents having 3 to 19 carbon atoms such as propylene glycol monomethyl ether; and the like.

Examples of the ether solvent include:
dialkyl ether solvents such as diethyl ether, dipropyl ether, dibutyl ether, dipentyl ether, diisoamyl ether, dihexyl ether, and diheptyl ether;
cyclic ether solvents such as tetrahydrofuran and tetrahydropyran;
aromatic ring-containing ether solvents such as diphenyl ether and anisole; and the like.

Examples of the ketone solvent include:
chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;
cyclic ketone solvents such as cyclopentanone, cyclohexanone, cycloheptanone, cyclooctanone, and methylcyclohexanone;
2,4-pentanedione, acetonylacetone, and acetophenone; and the like.

Examples of the amide solvent include:
cyclic amide solvents such as N,N′-dimethylimidazolidinone and N-methylpyrrolidone;
chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:
monocarboxylic acid ester solvents such as n-butyl acetate and ethyl lactate;
lactone solvents such as γ-butyrolactone and valerolactone;
polyhydric alcohol carboxylate solvents such as propylene glycol acetate;
polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:
aliphatic hydrocarbon solvents having 5 to 12 carbon atoms such as n-pentane and n-hexane;
aromatic hydrocarbon solvents having 6 to 16 carbon atoms such as toluene and xylene; and the like.

The organic solvent (D) is preferably the alcohol solvent, the ketone solvent, the ester solvent or a combination of the same, more preferably the aliphatic monohydric alcohol solvent having 1 to 18 carbon atoms, the polyhydric alcohol partial ether solvent having 3 to 19 carbon atoms, the chain ketone solvent, the monocarboxylic acid ester solvent, the lactone solvent, the polyhydric alcohol partial ether carboxylate solvent, or a combination of the same, and still more preferably diacetone alcohol, propylene glycol monomethyl ether, cyclohexanone, ethyl lactate, γ-butyrolactone, propylene glycol monomethyl ether acetate, or a combination of the same.

In the case in which the composition (I) contains the organic solvent (D), the lower limit of a proportion of the organic solvent (D) with respect to total components contained in the composition (I) is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### (F) Polymer

The polymer (F) is a polymer that differs from the polymer (A1), and has a percentage content of fluorine atoms which is greater than that of the polymer (A1). In general, a more hydrophobic polymer than a polymer that serves as a base polymer tends to be localized in a resist film surface layer. Since the polymer (F) has a percentage content of fluorine atoms which is greater than that of the polymer (A1), due to characteristics resulting from the hydrophobicity, the polymer (F) tends to be localized in the resist film surface layer. As a result, in the case in which the composition (I) contains the polymer (F), a cross-sectional shape of a resist pattern to be formed is expected to be favorable. The composition (I) may contain the polymer (F) as, for example, a surface conditioning agent of a resist film. The composition (I) may contain one type, or two or more types of the polymer (F).

### Other Optional Component(s)

The other optional component(s) is/are exemplified by a surfactant and the like. The composition (I) may contain one, or two or more types each of the other optional component(s).

### Composition (II)

The composition (II) contains the polymer (A2) and the acid generating agent (B). The composition (II) typically contains the organic solvent (D). The composition (II) may contain, as a favorable component, the acid diffusion control agent (C). The composition (II) may contain, as a favorable component, the polymer (F). The composition (II) may contain, within a range not leading to impairment of the effects of the present invention, other optional component(s).

Due to containing the polymer (A2) and the acid generating agent (B), the composition (II) is superior in sensitivity and results in superiority in the CDU performance and the ability to inhibit development defects. Although not necessarily clarified and without wishing to be bound by any theory, the reason for achieving the aforementioned effects by the composition (II) due to involving such a constitution may be presumed to be, for example, as in the following. Due to the polymer (A2) having the above-described structural unit (I) and structural unit (IIa), solubility or insolubility in a developer solution in light-exposed regions improves. It is considered that as a result, the composition (II) is superior in sensitivity, and results in superiority in the CDU performance and the ability to inhibit development defects.

The polymer (A2) is a polymer which has the above-described structural unit (I) and structural unit (IIa). In other words, the polymer (A2) is encompassed within the polymer (A1), and the polymer (A1) which has the structural unit (IIa) is the polymer (A2). Therefore, the parts of the polymer (A2) that are in common with the polymer (A1) are supported by the descriptions in the section “(A1) Polymer”.

Furthermore, the acid generating agent (B) and the organic solvent (D) contained in the composition (II), and well as the acid diffusion control agent (C) and the other optional component(s) are supported by the descriptions in the section “Composition (I)”.

### Method of Forming Resist Pattern

The method of forming a resist pattern according to an other embodiment of the present disclosure includes: a step (hereinafter, may be also referred to as “applying step”) of applying a radiation-sensitive resin composition directly or indirectly on a substrate; a step (hereinafter, may be also referred to as “exposing step”) of exposing a resist film formed by the applying step; and a step (hereinafter, may be also referred to as “developing step”) of developing the resist film exposed.

In the applying step, the composition (I) or the composition (II) is used as the radiation-sensitive resin composition. Thus, the method of forming a resist pattern of the other embodiment of the present disclosure enables forming a resist pattern being superior in CDU and in which the occurrence of development defects is inhibited, with high sensitivity.

Each step included in the method of forming a resist pattern is described below.

### Applying Step

In this step, the radiation-sensitive resin composition is applied directly or indirectly on the substrate. By this step, the resist film is formed directly or indirectly on the substrate.

In this step, the composition (I) or the composition (II) is used as the radiation-sensitive resin composition.

The substrate is exemplified by a conventionally well-known substrate such as a silicon wafer and a wafer coated with silicon dioxide or aluminum, and the like.

An application procedure is exemplified by spin coating, cast coating, roll coating, and the like. After the application, prebaking (hereinafter, may be also referred to as “PB”) may be carried out as needed for evaporating the solvent remaining in the coating film. The lower limit of a PB temperature is preferably 60° C., and more preferably 80° C. The upper limit of the PB temperature is preferably 150° C., and more preferably 140° C. The lower limit of a PB time period is preferably 5 sec, and more preferably 10 sec. The upper limit of the PB time period is preferably 600 sec, and more preferably 300 sec. The lower limit of an average thickness of the resist film formed is preferably 10 nm, and more preferably 20 nm. The upper limit of the average thickness is preferably 1,000 nm, and more preferably 500 nm.

### Exposing Step

In this step, the resist film formed by the applying step is exposed. This exposure is carried out by irradiation with an exposure light through a photomask (as the case may be, through a liquid immersion medium such as water). As the exposure light, far ultraviolet rays, EUV, or electron beams are preferred; an ArF excimer laser beam (wavelength: 193 nm), a KrF excimer laser beam (wavelength: 248 nm), EUV (wavelength: 13.5 nm), or electron beams are more preferred; a KrF excimer laser beam, EUV, or electron beams are still more preferred; and EUV or electron beams are particularly preferred.

It is preferred that post exposure baking (hereinafter, may be also referred to as “PEB”) is carried out after the exposure. This PEB enables an increase in a difference in solubility of the resist film in a developer solution between the light-exposed regions and light-unexposed regions. The lower limit of a temperature of the PEB is preferably 50° C., more preferably 80° C., and still more preferably 100° C. The upper limit of the temperature of the PEB is preferably 180° C., and more preferably 130° C. The lower limit of a time period of the PEB is preferably 5 sec, more preferably 10 sec, and still more preferably 30 sec. The upper limit of the time period of the PEB is preferably 600 sec, more preferably 300 sec, and still more preferably 100 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene; and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. Exemplary organic solvents include the solvents exemplified as the organic solvent (D) for the radiation-sensitive resin composition, and the like.

### Polymer

The polymer of a still other embodiment of the present disclosure is described as the polymer (A2) in the composition (II). The polymer can be suitably used as a component of the radiation-sensitive resin composition.

### EXAMPLES

Hereinafter, the present disclosure is explained in detail by way of Examples, but the present invention is not in any way limited to these Examples. Measuring methods for various types of physical property values are shown below.

### Weight Average Molecular Weight (Mw), Number Average Molecular Weight (Mn), and Polydispersity Index (Mw/Mn)

Measurements of the Mw and the Mn of the polymer were carried out in accordance with the conditions described in the aforementioned paragraph “Method for Measuring Mw and Mn”. The polydispersity index (Mw/Mn) of the polymer was calculated from the measurement results of the Mw and the Mn.

### Synthesis of Polymer (A)

### Synthesis Examples: Synthesis of Polymers (P-1) to (P-7)

The respective monomers were combined and subjected to a copolymerization reaction in a tetrahydrofuran (THF) solvent, and the reaction products were crystallized in methanol. Furthermore, the resulting product was repeatedly washed with hexane, followed by isolation and drying to give polymers (hereinafter, may be also referred to as “polymers (P-1) to (P-7)”) represented by the following formulae (P-1) to (P-7). A constitution of each polymer (A) thus obtained was measured by using 1H-NMR. It is to be noted that in the following formulae (P-1) to (P-7), the numerical value shown to the lower right of each structural unit indicates a proportion (molar ratio) of each structural unit with respect to the total structural units constituting the polymer (A).

The Mw and the Mw/Mn of the polymers (P-1) to (P-7) were as follows.
P-1: Mw=8,100, Mw/Mn=1.7
P-2: Mw=8,300, Mw/Mn=1.7
P-3: Mw=8,200, Mw/Mn=1.7
P-4: Mw=8,600, Mw/Mn=1.7
P-5: Mw=9,700, Mw/Mn=1.7
P-6: Mw=8,300, Mw/Mn=1.6
P-7: Mw=9,200, Mw/Mn=1.7

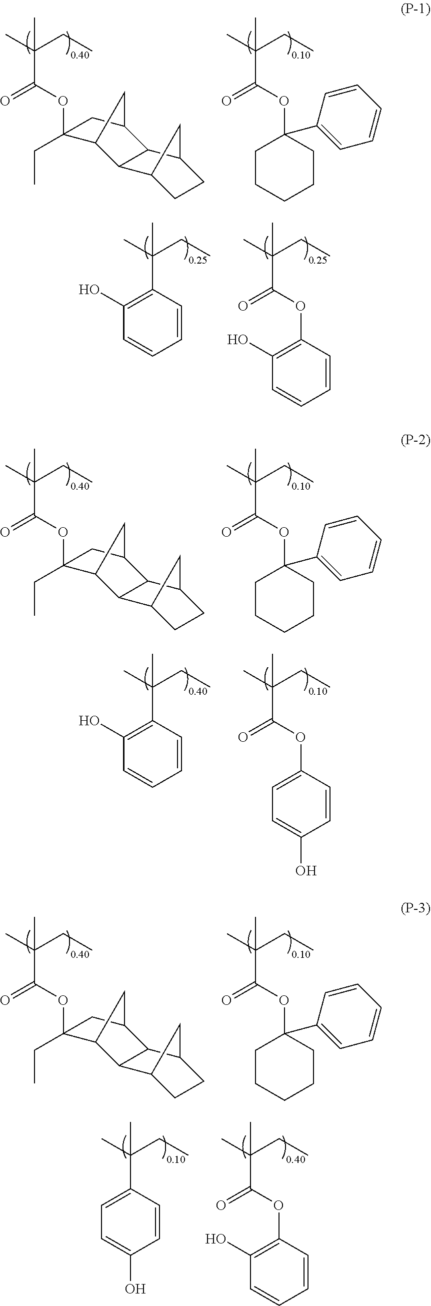

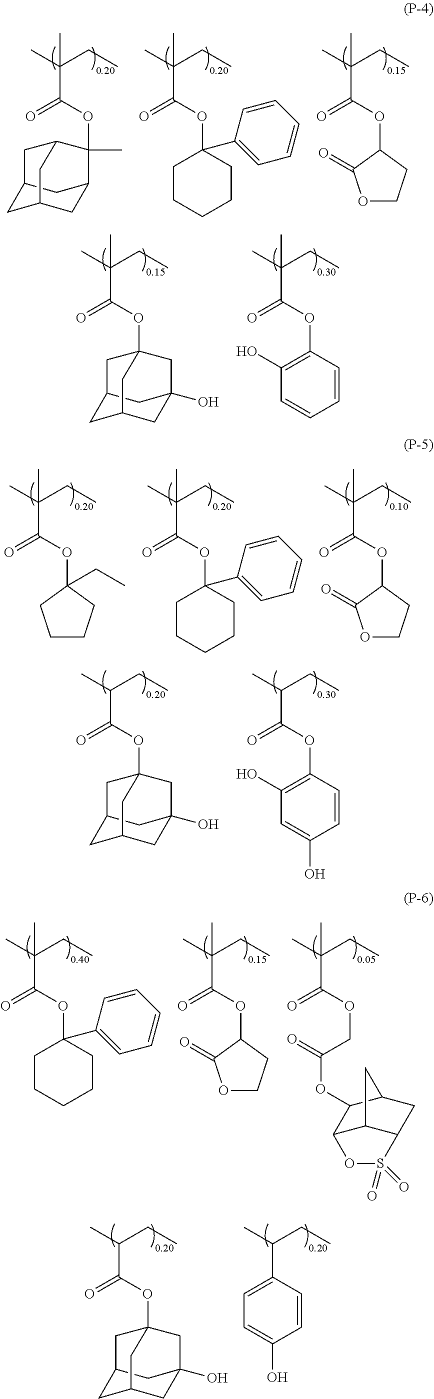

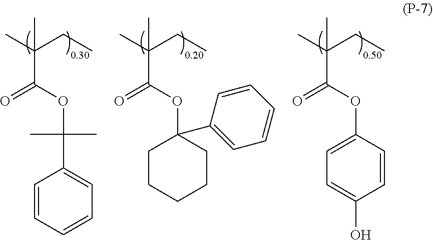

### Preparation of Radiation-Sensitive Resin Composition

The acid generating agent (B), the acid diffusion control agent (C), the organic solvent (D), and the polymer (F) used for preparing the radiation-sensitive resin composition are shown below. In the following Examples and Comparative Examples, unless otherwise specified particularly, the term “parts by mass” means a value, provided that the mass of the polymer (A) used was 100 parts by mass.

### (B) Acid Generating Agent

Compounds (hereinafter, may be also referred to as “acid generating agents (PAG1) to (PAG9)”) represented by the following formulae (PAG1) to (PAG9) were used as the acid generating agent (B). The acid generating agents (PAG7) to (PAG9) fall under the compound (Z).

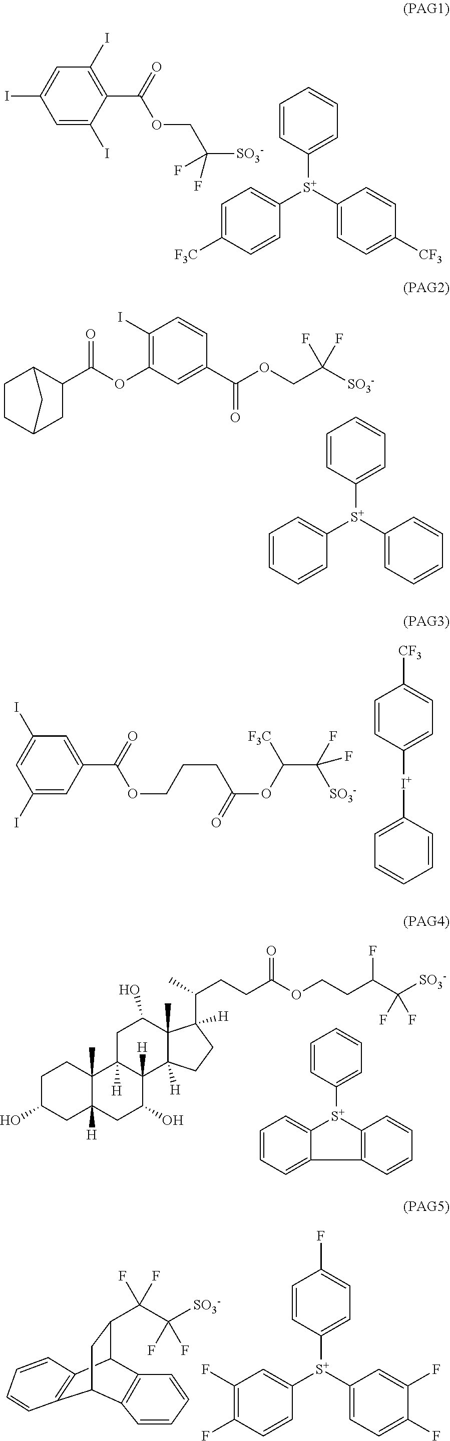

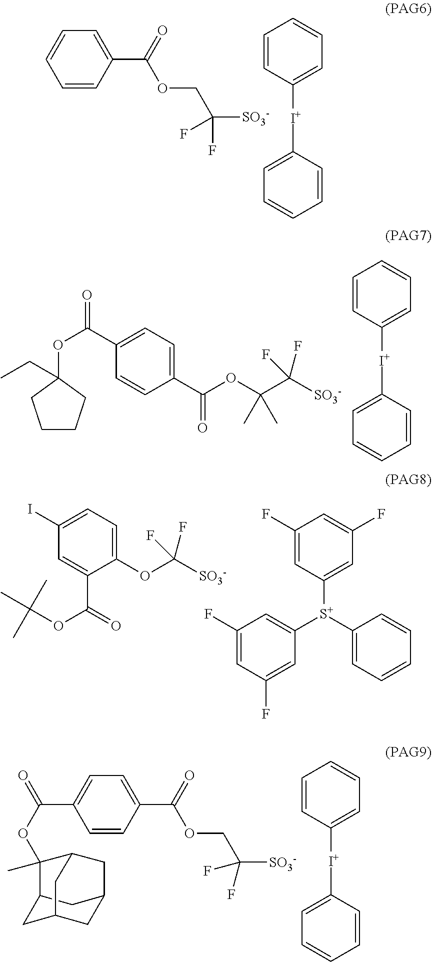

### (C) Acid Diffusion Control Agent

Compounds (hereinafter, may be also referred to as “acid diffusion control agents (Q-1) to (Q-10)”) represented by the following formulae (Q-1) to (Q-10) were used as the acid diffusion control agent (C). Acid diffusion control agents (Q-6), (Q-7), (Q-9), and (Q-10) fall under the compound (Z).

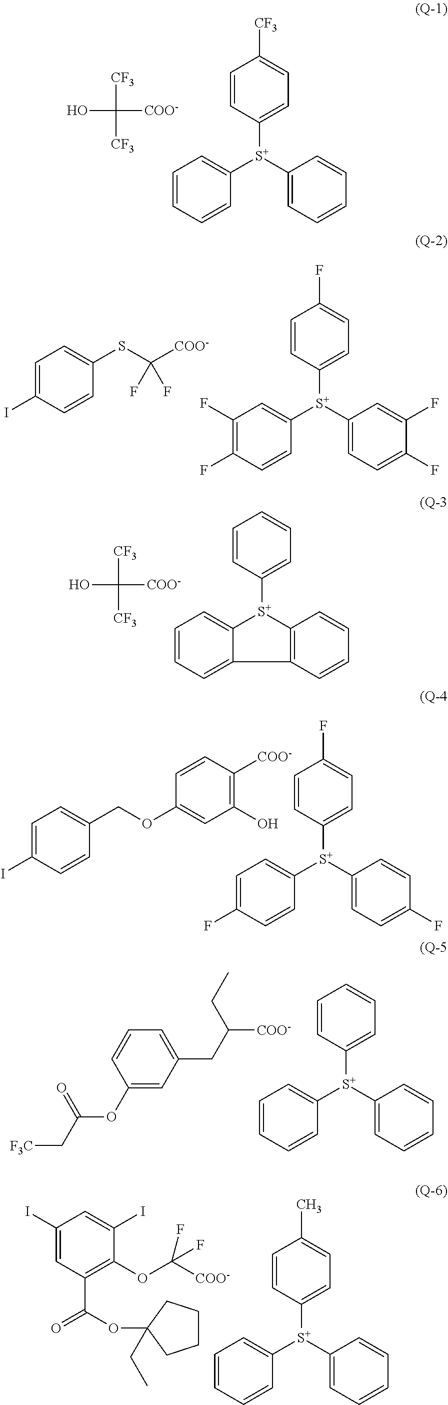

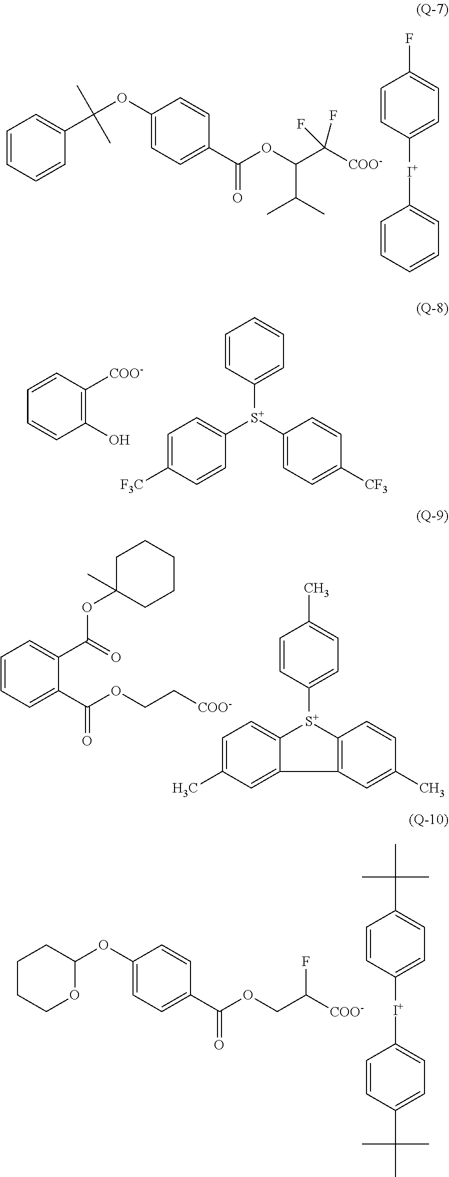

### (D) Organic Solvent

Organic solvents shown below were used as the organic solvent (D).
PGMIEA: propylene glycol monomethyl ether acetate
GBL: γ-butyrolactone
CHN: cyclohexane
PGME: propylene glycol monomethyl ether
DAA: diacetone alcohol
EL: ethyl lactate

### (F) Polymer

A compound (hereinafter, may be also referred to as “polymer F-1”) represented by the following formula (F-1) was used as the polymer (F). In the following formula (F-1), the numerical value shown to the bottom right of each structural unit indicates the proportion (molar ratio) of the structural unit with respect to the total structural units constituting the polymer (F). The Mw and the Mw/Mn of the polymer (F-1) were as shown below.
F-1: Mw=8,900, Mw/Mn=2.0

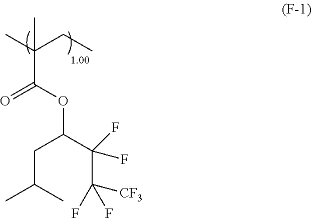

### Examples 1 to 14 and Comparative Examples 1 to 4

A surfactant (“FC-4430”, available from 3M Company) was dissolved in the organic solvent (D) shown in Table 1 below at a concentration of 100 ppm, and then each component shown in Table 1 below was dissolved therein. A mix liquid thus obtained was filtered through a membrane filter having a pore size of 0.2 μm to prepare each radiation-sensitive resin composition.

### Evaluations

Using each radiation-sensitive resin composition prepared as described above, the sensitivity, the CDU performance, and the ability to inhibit development defects were evaluated in accordance with the following methods. The results of the evaluations are shown in Table 1 below.

### Sensitivity

An underlayer antireflective film having an average thickness of 105 nm was formed by applying a composition for underlayer antireflective film formation (“ARC66,” available from Brewer Science, Inc.) on a 12-inch silicon wafer using a spin-coater (“CLEAN TRACK ACT 12,” available from Tokyo Electron Limited), and thereafter heating the composition at 205° C. for 60 sec. Each radiation-sensitive resin composition prepared as described above was applied on the underlayer antireflective film using the spin-coater, and subjected to prebaking (PB) at 130° C. for 60 sec. Thereafter, by cooling at 23° C. for 30 sec, a resist film having an average thickness of 55 nm was formed. This resist film was exposed with an EUV scanner (“NXE3300”, available from ASML Co.: NA of 0.33, σ0.9/0.6, quadruple pole illumination, mask of a hole pattern with a dimension on the wafer of pitch: 46 nm, +20% bias). Post-exposure baking (PEB) was carried out on a hot plate at 120° C. for 60 sec, and development was performed with a 2.38% by mass aqueous tetramethylammonium hydroxide (TMAH) solution for 30 sec, whereby a resist pattern having 23 nm holes and 46 nm pitches was formed. An exposure dose at which this resist pattern with the 23 nm holes and 46 nm pitches was formed was defined as an optimum exposure dose (Eop [mJ/cm²]). The Eop being smaller indicates more favorable sensitivity.

### CDU Performance

A resist pattern with 23 nm holes and 46 nm pitches was formed through irradiation with the Eop exposure dose determined above, in a similar manner to the above operation. The resist pattern thus formed was observed from above using a scanning electron microscope (“CG-5000”, available from Hitachi High-Technologies Corporation). Hole diameters were measured at 16 sites in an area of 500 nm, and the averaged value was determined. Furthermore, the average value was measured at 500 arbitrary sites in total. A 3 Sigma value was determined from distribution of the measurement values, and thus determined 3 Sigma value was defined as “CDU” (unit: nm). The CDU value being lower indicates the CDU performance being more favorable, revealing less variance of the hole diameters in greater ranges. The CDU performance is more favorable as the CDU becomes lower.

### Ability to Inhibit Development Defects

An underlayer antireflective film having an average thickness of 105 nm was formed by applying the composition for underlayer antireflective film formation on a 12-inch silicon wafer using the spin-coater, and thereafter heating the composition at 205° C. for 60 sec. Each radiation-sensitive resin composition prepared as described above was applied on the underlayer antireflective film using the spin-coater, and subjected to PB at 130° C. for 60 sec. Thereafter, by cooling at 23° C. for 30 sec, a resist film having an average thickness of 55 nm was formed. Next, the resist film was exposed using the above-described EUV scanner (“NXE3300,” available from ASML Co.) with NA of 0.33 under an illumination condition of Conventional s=0.89, and with a mask of imecDEFECT32FFR02. After the exposure, the resist film was subjected to PEB at 120° C. for 60 sec. Thereafter, the resist film was subjected to development with an alkali by using a 2.38% by mass aqueous TMAH solution as an alkaline developer solution. After the development, washing with water was carried out, followed by drying, to form a positive-tone resist pattern (32 nm line-and-space pattern), which was then prepared to be a wafer for defect testing. The number of defects on this wafer for defect testing was measured using a defect-testing apparatus (“KLA2810”, manufactured by KLA-Tencor). The number of defects after development was evaluated to be: “A” (extremely favorable) in a case in which the number of defects assessed to be derived from the resist film was no greater than 15; “B” (favorable) in a case in which this number was greater than 15 and no greater than 40; and “C” (unfavorable) in a case in which this number was greater than 40.

TABLE 1

| | (A) | (B) Acid | (C) Acid | | (F) | | | Ability to |
|---|---|---|---|---|---|---|---|---|
| | Polymer | generating | diffusion control | (D) Organic | Polymer | | | inhibit |
| | (parts | agent (parts | agent (parts | solvent (parts | (parts | Eop | CDU | development |
| | by mass) | by mass) | by mass) | by mass) | by mass) | (mJ/cm²) | (nm) | defects |
| Example 1 | P-1 | PAG1 | Q-1 | PGMEA/CHN/PGME | F-1 | 14 | 2.2 | A |
| | (100) | (5.0) | (3.0) | (400/2,000/100) | (3.0) | | | |
| Example 2 | P-2 | PAG2 | Q-2 | PGMEA/CHN/PGME | F-1 | 12 | 2.2 | B |
| | (100) | (4.5) | (2.0) | (400/2,000/100) | (3.0) | | | |
| Example 3 | P-3 | PAG3 | Q-3 | PGMEA/CHN/PGME | F-1 | 15 | 2.2 | B |
| | (100) | (4.5) | (3.5) | (400/2,000/100) | (3.0) | | | |
| Example 4 | P-4 | PAG4 | Q-4 | PGMEA/DAA | F-1 | 15 | 2.2 | A |
| | (100) | (5.0) | (3.0) | (2,000/500) | (3.0) | | | |
| Example 5 | P-5 | PAG4 | Q-5 | PGMEA/GBL | F-1 | 14 | 2.4 | B |
| | (100) | (5.0) | (3.0) | (2,200/300) | (3.0) | | | |
| Example 6 | P-6 | PAG5 | Q-6 | PGMEA/EL | F-1 | 14 | 2.4 | A |
| | (100) | (7.0) | (3.0) | (2,000/500) | (3.0) | | | |
| Example 7 | P-6 | PAG6 | Q-7 | PGMEA/EL | F-1 | 13 | 2.2 | B |
| | (100) | (6.0) | (3.0) | (2,000/500) | (3.0) | | | |
| Example 8 | P-7 | PAG7 | Q-5 | PGMEA/GBL | F-1 | 16 | 2.4 | A |
| | (100) | (7.0) | (4.0) | (2,200/300) | (3.0) | | | |
| Example 9 | P-7 | PAG8 | Q-8 | PGMEA/GBL | F-1 | 13 | 2.2 | A |
| | (100) | (7.0) | (3.0) | (2,200/300) | (3.0) | | | |
| Example 10 | P-3 | PAG3 | Q-9 | PGMEA/CHN/PGME | F-1 | 15 | 2.2 | A |
| | (100) | (4.5) | (3.5) | (400/2,000/100) | (3.0) | | | |
| Example 11 | P-3 | PAG3 | Q-10 | PGMEA/CHN/PGME | F-1 | 15 | 2.2 | A |
| | (100) | (4.5) | (3.5) | (400/2,000/100) | (3.0) | | | |
| Example 12 | P-7 | PAG3 | Q-10 | PGMEA/CHN/PGME | F-1 | 15 | 2.2 | B |
| | (100) | (4.5) | (3.5) | (400/2,000/100) | (3.0) | | | |
| Example 13 | P-5 | PAG9 | Q-5 | PGMEA/GBL | F-1 | 14 | 2.4 | A |
| | (100) | (5.0) | (3.0) | (2,200/300) | (3.0) | | | |
| Example 14 | P-5 | PAG9 | Q-9 | PGMEA/GBL | F-1 | 14 | 2.4 | A |
| | (100) | (5.0) | (3.0) | (2,200/300) | (3.0) | | | |
| Comparative | P-6 | PAG6 | Q-4 | PGMEA/EL | F-1 | 13 | 2.2 | C |
| Example 1 | (100) | (6.0) | (3.0) | (2,000/500) | (3.0) | | | |
| Comparative | P-6 | PAG5 | Q-5 | PGMEA/CHN/PGME | F-1 | 13 | 2.4 | C |
| Example 2 | (100) | (7.0) | (3.0) | (400/2,000/100) | (3.0) | | | |
| Comparative | P-7 | PAG1 | Q-8 | PGMEA/CHN/PGME | F-1 | 14 | 2.2 | C |
| Example 3 | (100) | (5.0) | (3.0) | (400/2,000/100) | (3.0) | | | |
| Comparative | P-7 | PAG4 | Q-1 | PGMEA/DAA | F-1 | 16 | 2.4 | C |
| Example 4 | (100) | (5.0) | (3.0) | (2,000/500) | (3.0) | | | |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive resin composition comprising:
a polymer comprising a first structural unit represented by formula (1), solubility of the polymer in a developer solution being capable of being altered by an action of an acid; and
a compound represented by formula (2): 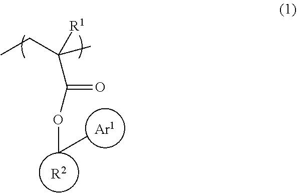
wherein,
in the formula (1),
R¹ represents a hydrogen atom, a fluorine atom, a methyl group, or a trifluoromethyl group;
R² represents a group obtained by removing, from a substituted or unsubstituted aliphatic hydrocarbon ring having 3 to 30 ring atoms, two hydrogen atoms which bond to one carbon atom; and
Ar¹ represents a group obtained by removing one hydrogen atom from a substituted or unsubstituted aromatic hydrocarbon ring having 6 to 30 ring atoms, and 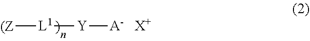
in the formula (2),
Z represents an acid-labile group;
L¹ represents *—O—CO— or —O—, wherein * denotes a site bonding to Z;
Y represents an organic group having 1 to 30 carbon atoms and having a valency of (n+1), the organic group not comprising a cyclic acetal structure;
A⁻ represents a monovalent anion group;
n is an integer of 1 to 5, wherein in a case in which n is no less than 2, two or more Zs are identical or different from each other, and two or more L¹s are identical or different from each other; and
X⁺ represents a monovalent radiation-sensitive onium cation.

2. The radiation-sensitive resin composition according to claim 1, wherein A⁻ in the formula (2) represents SO₃⁻; or COO⁻.

3. The radiation-sensitive resin composition according to claim 1, wherein A⁻ in the formula (2) represents SO₃⁻.

4. The radiation-sensitive resin composition according to claim 1, wherein Y in the formula (2) comprises, as a ring structure, only an aliphatic hydrocarbon ring, an aromatic hydrocarbon ring, an aromatic heterocyclic ring, or a combination thereof.

5. The radiation-sensitive resin composition according to claim 1, wherein the polymer further comprises a second structural unit represented by formula (3-1): 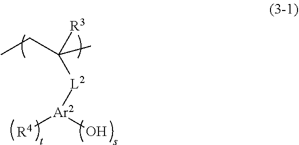
wherein, in the formula (3-1),
R³ represents a hydrogen atom, a fluorine atom, a methyl group, or a trifluoromethyl group;
L² represents a single bond, —COO—, —O—, or —CONH—;
Ar² represents a group obtained by removing (s+t+1) hydrogen atoms from an aromatic hydrocarbon ring having 6 to 30 ring atoms;
s is an integer of 1 to 3; and
t is an integer of 0 to 8, wherein
in a case in which tis 1, R⁴ represents a halogen atom or a monovalent organic group having 1 to 20 carbon atoms, and
in a case in which t is no less than 2, a plurality of R⁴s are identical or different from each other, and each R⁴ represents a halogen atom or a monovalent organic group having 1 to 20 carbon atoms, or two or more of the plurality of R⁴s taken together represent an aliphatic ring having 4 to 20 ring atoms together with the carbon chain to which the two or more of the plurality of R⁴s bond.

6. The radiation-sensitive resin composition according to claim 4, wherein, in the formula (3-1),
in a case in which s is 1, the hydroxy group bonds to, of the carbon atoms constituting Ar², the carbon atom adjacent to the carbon atom which bonds to L², and
in a case in which s is no less than 2, at least one of the hydroxy groups bonds to, of the carbon atoms constituting Ar², the carbon atom adjacent to the carbon atom which bonds to L².

7. A radiation-sensitive resin composition comprising:
a polymer comprising: a first structural unit represented by formula (1); and a third structural unit represented by formula (3-2), solubility of the polymer in a developer solution being capable of being altered by an action of an acid; and
a radiation-sensitive acid generating agent, 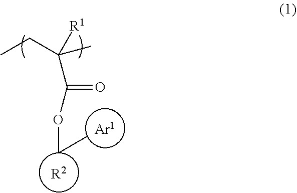
wherein,
in the formula (1),
R¹ represents a hydrogen atom, a fluorine atom, a methyl group, or a trifluoromethyl group;
R² represents a group obtained by removing, from a substituted or unsubstituted aliphatic hydrocarbon ring having 3 to 30 ring atoms, two hydrogen atoms which bond to one carbon atom; and
Ar¹ represents a group obtained by removing one hydrogen atom from a substituted or unsubstituted aromatic hydrocarbon ring having 6 to 30 ring atoms, and 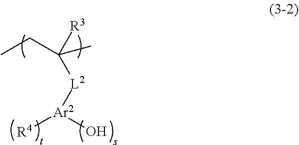
in the formula (3-2),
R³ represents a hydrogen atom, a fluorine atom, a methyl group, or a trifluoromethyl group;
L² represents a single bond, —COO—, —O—, or —CONH—;
Ar² represents a group obtained by removing (s+t+1) hydrogen atoms from an aromatic hydrocarbon ring having 6 to 30 ring atoms;
s is an integer of 1 to 3, wherein
in a case in which s is 1, the hydroxy group bonds to, of the carbon atoms constituting Ar², the carbon atom adjacent to the carbon atom which bonds to L², and
in a case in which s is no less than 2, at least one of the hydroxy groups bonds to, of the carbon atoms constituting Ar², the carbon atom adjacent to the carbon atom which bonds to L²; and
t is an integer of 0 to 8, wherein
in a case in which tis 1, R⁴ represents a halogen atom or a monovalent organic group having 1 to 20 carbon atoms, and
in a case in which t is no less than 2, a plurality of R⁴s are identical or different from each other, and each R⁴ represents a halogen atom or a monovalent organic group having 1 to 20 carbon atoms, or two or more of the plurality of R⁴s taken together represent an aliphatic ring having 4 to 20 ring atoms together with the carbon chain to which the two or more of the plurality of R⁴s bond.

8. A method of forming a resist pattern, the method comprising:
applying the radiation-sensitive resin composition according to claim 1 directly or indirectly on a substrate to form a resist film;
exposing the resist film; and
developing the resist film exposed.

9. A method of forming a resist pattern, the method comprising:
applying the radiation-sensitive resin composition according to claim 7 directly or indirectly on a substrate to form a resist film;
exposing the resist film; and
developing the resist film exposed.

10. A polymer comprising:
a first structural unit represented by formula (1); and
a third structural unit represented by formula (3-2): 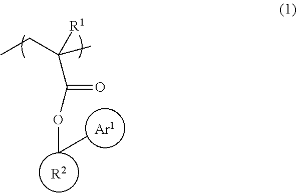
wherein,
in the formula (1),
R¹ represents a hydrogen atom, a fluorine atom, a methyl group, or a trifluoromethyl group;
R² represents a group obtained by removing, from a substituted or unsubstituted aliphatic hydrocarbon ring having 3 to 30 ring atoms, two hydrogen atoms which bond to one carbon atom; and
Ar¹ represents a group obtained by removing one hydrogen atom from a substituted or unsubstituted aromatic hydrocarbon ring having 6 to 30 ring atoms, and 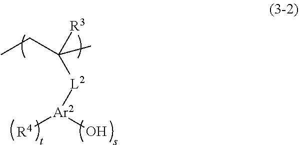
in the formula (3-2),
R³ represents a hydrogen atom, a fluorine atom, a methyl group, or a trifluoromethyl group;
L² represents a single bond, —COO—, —O—, or —CONH—;
Ar² represents a group obtained by removing (s+t+1) hydrogen atoms from an aromatic hydrocarbon ring having 6 to 30 ring atoms;
s is an integer of 1 to 3, wherein
in a case in which s is 1, the hydroxy group bonds to, of the carbon atoms constituting Ar², the carbon atom adjacent to the carbon atom which bonds to L², and
in a case in which s is no less than 2, at least one of the hydroxy groups bonds to, of the carbon atoms constituting Ar², the carbon atom adjacent to the carbon atom which bonds to L²; and
t is an integer of 0 to 8, wherein
in a case in which t is 1, R⁴ represents a halogen atom or a monovalent organic group having 1 to 10 carbon atoms, and
in a case in which t is no less than 2, a plurality of R⁴s are identical or different from each other, and each R⁴ represents a halogen atom or a monovalent organic group having 1 to 10 carbon atoms, or two or more of the plurality of R⁴s taken together represent an aliphatic ring having 4 to 20 ring atoms together with the carbon chain to which the two or more of the plurality of R⁴s bond.
